(19) United States
(12) Patent Application Publication
(10) Pub. No.: US 2018/0259335 A1
(43) Pub. Date: Sep. 13, 2018

(54) Gyroscope

(71) Applicant: Hitachi, Ltd., Chiyoda-ku, Tokyo (JP)

(72) Inventors: Joan GINER, Tokyo (JP); Yuhua ZHANG, Tokyo (JP); Daisuke MAEDA, Tokyo (JP)

(21) Appl. No.: 15/761,002

(22) PCT Filed: Sep. 30, 2015
(86) PCT No.: PCT/JP2015/077698

§ 371 Date: Mar. 16, 2018

(51) Int. Cl. G01C 19/5762; G01C 19/5747; G01P 3/44; G01C 19/5712; G01C 19/56; B81B 3/00

(52) U.S. Cl. CPC G01C 19/5762; G01C 19/5747; G01P 3/44; B81B 2201/0242; G01P 9/04; B81B 3/0048; G01C 19/5712

(57) ABSTRACT

A gyroscope includes connecting portions which are provided between a mass body and a mass body and connects the mass body with the mass body. Here, the connecting portions includes a fixing portion fixed to a substrate, a shuttle provided between the fixing portion and the mass body, a shuttle provided between the fixing portion and the mass body, a beam connecting the fixing portion with the shuttle, a beam connecting the fixing portion with the shuttle, a beam connecting the mass body with the shuttle, a beam connecting the mass body with the shuttle, and a beam connecting the shuttle with the shuttle. The fixing portion is provided between the shuttle and the shuttle.

### TECHNICAL FIELD

The present invention relates to a gyroscope, and relates to, for example, a technique effective when applied to gyroscope formed using Micro Electro Mechanical Systems (MEMS) technique.

### BACKGROUND ART

In NPL 1, a technique relating to a gyroscope detecting a rotation angle based on the principle or Foucault pendulum is described.

### CITATION LIST

### Non-Patent Literature

NPL 1: D. Senkal, A. Efimovskaya, and A. M. Shkel, “Minimal Realisation of Dynamically Balanced Lumped Mass WA Gyroscope: Dual Foucault Pendulum,” Inertial Sensors and Systems (ISISS), 2015 IEEE International Symposium on, pp. 1-2, 2015.

### SUMMARY OF INVENTION

### Technical Problem

For example, a navigation system is expected to be used in wide field such as personal navigation, military navigation, a vehicle side slip prevention system, a virtual reality system, an unmanned airplane, and so on. The basic component of the navigation system is a gyroscope. The gyroscope is a sensor capable of detecting an angular velocity, and determines a rotation angle from the angular velocity in the navigation system.

As a general gyroscope, there are an optical gyroscope, a gyroscope using a rotating mass body, and the like, but these gyroscopes are large in size and heavy. Further, these gyroscopes are expensive and have high power consumption. In this regard, in the trend of the current industry, miniaturisation and high performance of a gyroscope are desired, and the above-mentioned gyroscope does not follow the trend.

Here, in recent years, a gyroscope using an MEMS technique has been introduced, and the gyroscope using the MEMS technique follows the above-mentioned trend, and has a potential to realize miniaturization and high performance. Further, the gyroscope using MEMS technique is excellent in mass productivity and has advantages that low cost can be realized.

For example, a vibration gyroscope using the MEMS technique is a gyroscope that detects an angular velocity by detecting energy coupling between mutually orthogonal vibrations according to the Coriolis principle. Specifically, when an angular velocity around a z-direction is applied while a vibration gyroscope vibrates in an x-direction, Coriolis force causes vibration in the y-direction. The vibration gyroscope can detect an angular velocity around the z-direction by measuring the magnitude of the vibration in the y-direction.

However, the current vibration gyroscope which operates like this is unsuitable for use in a navigation system. This is because the navigation system needs to calculate a rotation angle and the current vibration gyroscope calculates a rotation angle by integrating detected angular velocity with time. That is, there are bias error and drift error when detecting for example, an angular velocity. However, if the angular velocity is integrated to calculate a rotation angle, at the same time, the bias error and the drift error accompanying the angular velocity are also integrated and these errors are amplified. In other words, in the navigation system, it is sometimes necessary to integrate the angular velocity over a long period of time, and in this case, the bias error and the drift error are also integrated, and the magnitude of the error increases. Therefore, in particular, in a vibration gyro sensor used in a navigation system, a study on suppressing amplification of errors is desired.

An object of the present invention is to provide a technique capable of improving the performance of gyroscope.

Other problems and novel features will become apparent from the description of this specification and the accompanying drawings.

### Solution to Problem

A gyroscope according to an embodiment includes a first mass body that is displaceable in a first direction and a second direction orthogonal to the first direction; a second mass body that is displaceable in the first direction and the second direction; and a connecting portion that is provided between the first mass body and the second mass body, and connects the first mass body with the second mass body. Here, the connecting portion includes a fixing portion fixed to a substrate, a first member provided between the fixing portion and the first mass body, a second member provided between the fixing portion and the second mass body, a first beam connecting the fixing portion with the first member, a second beam connecting the fixing portion with the second member, a third beam connecting the first mass body with the first member, a fourth beam connecting the second mass body with the second member, and a fifth beans connecting the first member with the second member. The fixing portion is provided between the first member and the second member.

A gyroscope according to another embodiment includes a first mass body that is displaceable in a first direction and a second direction orthogonal to the first direction; a second mass body that is displaceable in the first direction and the second direction; and a connecting portion that is provided between the first mass body and the second mass body, and connects the first mass body with the second mass body. Here, a first vibration driving unit vibrating the first mass body in the first direction, and a second vibration driving unit vibrating the first mass body in the second direction are formed inside the first mass body. Similarly, a third vibration driving unit vibrating the second mass body in the first direction, and a fourth vibration driving unit vibrating the second mass body in the second direction are formed inside the second mass body.

Further, a gyroscope according to still another embodiment includes a first mass body that is displaceable in a first direction and a second direction orthogonal to the first direction; a second mass body that is displaceable in the first direction and the second direction; and a connecting portion that is provided between the first mass body and the second mass body, and connects the first mass body with the second mass body. Here, in plan view, the first mass body has a concave portion toward the center of the first mass body. On the other hand, in plan view, the second mass body has a convex portion inserted into the concave portion through a gap. At this time, the connecting portion connects the concave portion with the convex portion.

### ADVANTAGEOUS EFFECTS OF INVENTION

According to an embodiment, performance improvement of a gyroscope can be achieved.

### BRIEF DESCRIPTION OF DRAWINGS

FIG. 1 is a diagram illustrating a planar configuration of a sensor element constituting a gyroscope in Embodiment 1.

FIG. 2 is a cross-sectional view taken along line A-A of FIG. 1.

FIG. 3 is a cross-sectional view taken along line B-B of FIG. 1.

FIG. 4 is a schematic diagram illustrating the conceptual planar structure of a connecting portion in Embodiment 1.

FIG. 5 is a plan view illustrating a specific configuration example of the connecting portion in Embodiment 1.

FIG. 6 is a plan view illustrating another specific configuration example of the connecting portion in Embodiment 1.

FIG. 7 is a diagram illustrating a circuit configuration for driving and vibrating a mass body using a vibration driving unit in Embodiment 1.

FIG. 8 is a schematic diagram illustrating a configuration example of the vibration driving unit.

FIG. 9 is a diagram illustrating a state in which a pair of mass bodies connected by a plurality of connecting portions is driven to vibrate in an x-direction.

FIGS. 10(a) and (b) are diagrams schematically illustrating a state in which a pair of mass bodies are driven to vibrate in opposite phases in the x-direction.

FIG. 11 is a diagram illustrating a state in which a pair of mass bodies connected by a plurality of connecting portions is driven to vibrate in a y-direction.

FIGS. 12(a) and (b) are diagrams schematically illustrating a state in which a pair of mass bodies are driven to vibrate in opposite phases in the y-direction.

FIG. 13 is a schematic diagram for explaining the operation of a sensor element in Embodiment 1 in a case where angular velocity is applied around s-direction (clockwise).

FIG. 14 is a diagram illustrating a configuration of a sensor system in Embodiment 1.

FIG. 15 is a relational expression illustrating the reciprocal (1/Q) of Q value in a gyroscope.

FIG. 16(a) is a schematic diagram illustrating a configuration in which a beam connected to the mass body is provided only on one side of the fixing portion, and FIG. 16(b) is a schematic diagram illustrating a configuration in which a beam connected to the mass body is provided on both sides of the fixing portion.

FIG. 17(a) is a diagram schematically illustrating ideal driven vibration in a case where an angular velocity is not applied, and FIG. 17(b) is a diagram schematically illustrating driven vibration in a state where erroneous detection occurs in a case where an angular velocity is not applied.

FIG. 18 is a diagram for explaining a concept of matching a spring constant in the x-direction and a spring constant in the y-direction.

FIG. 19 is a plan view illustrating a configuration of a sensor element of Modification Example 1.

FIG. 20 is a plan view illustrating a configuration of a sensor element of Modification Example 2.

FIG. 21 is a plan view illustrating a configuration of a sensor element of Modification Example 3.

FIG. 22 is a plan view illustrating a configuration of a sensor element of Modification Example 4.

FIG. 23 is a plan view illustrating a configuration of a sensor element of Modification Example 5.

FIGS. 24(a) and (b) are diagrams for explaining a room for improvement focused on Embodiment 2.

FIGS. 25(a) and (b) are diagrams for explaining the basic idea of Embodiment 2.

FIG. 26 is a plan view illustrating a configuration of a sensor element of Embodiment 2.

FIG. 27 is a cross-sectional view taken along line A-A of FIG. 26.

FIG. 28 is a cross-sectional view taken along line B-B of FIG. 26.

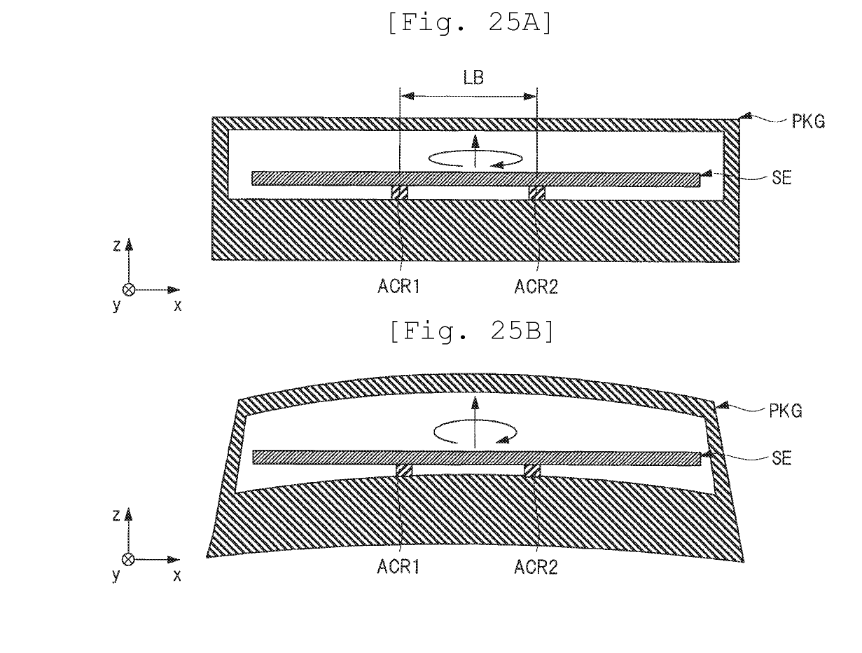

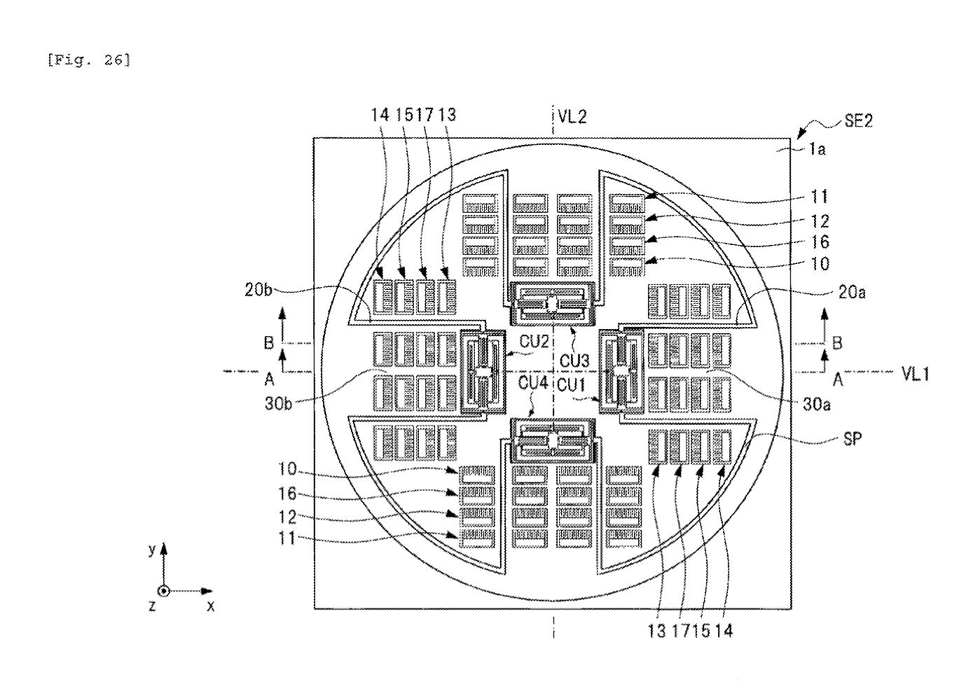

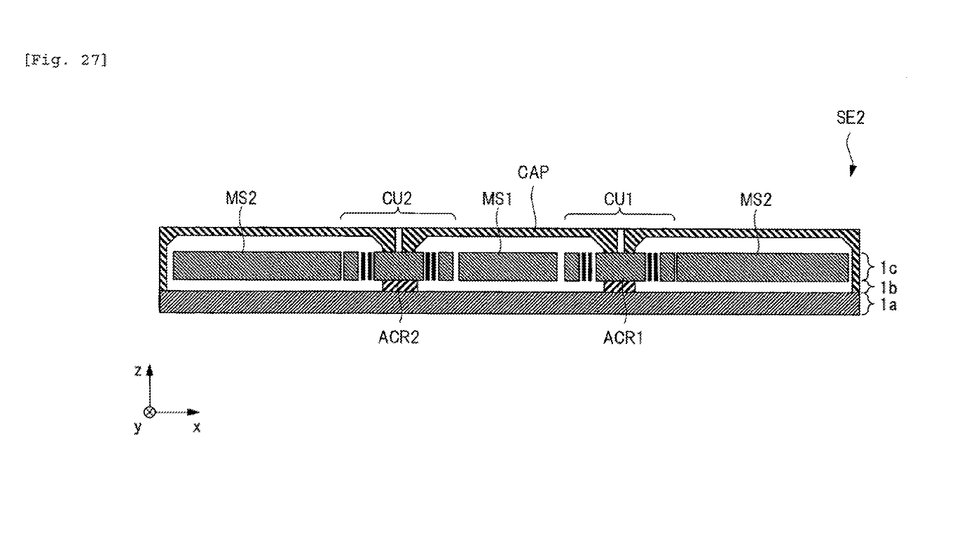

FIG. 25 is a schematic diagram illustrating a configuration example of the vibration driving unit.

FIG. 30 is a plan view illustrating a configuration of a sensor element in Modification Example.

### DESCRIPTION OF EMBODIMENTS

In the following embodiments, when necessary for convenience, a description will be made by separating the invention into a plurality of sections or embodiments, but unless otherwise specified, they are not unrelated to each other, one is in a relationship such as a modification, details, supplementary explanation, or the like of a part or the whole of the other.

Further, in the following embodiments, in a case of referring to the number of elements (including number, numerical value, quantity, range, or the like), except for a case where it is expressly specified, and a case where it is obviously limited to a specific number in principle, or the like, it is not limited the specific number, and it may be the specific number or more or less.

Furthermore, in the following embodiments, it goes without saying that the constituent elements (including element steps or the like) are not essential, except for the case where they are explicitly stated or the case where it is considered to be essential obviously in principle.

Similarly, in the following embodiments, when referring to shapes, positional relationships, or the like, except for the case where they are explicitly stated and the case where it is considered not to be essential obviously in principle it is assumed that shapes substantially approximate or similar to its shape and the like are included. This also applies to the above numerical value and range.

In addition, in all of the drawings for describing the embodiments, the same reference numerals will be given to the same members in principle, and the repetitive description thereof will be omitted. Even in a plan view, hatching may foe added to make drawings easy to see.

### Embodiment 1

<Usefulness of Rate Integrating Gyroscope>

Since the technical idea in Embodiment 1 is a technical idea targeting a rate integrating gyroscope, first, the usefulness of the rate integrating gyroscope will be described.

A vibration gyroscope using the MEMS technique is a gyroscope that detects an angular velocity by detecting energy coupling between mutually orthogonal vibrations according to the Coriolis principle. Examples of the vibration gyroscope are rate gyroscopes. In the rate gyroscope, when an angular velocity around the z-direction is applied in a state where the mass body is driven and vibrates in for example, the x-direction, Coriolis force causes vibration in the y-direction in the mass body. Since the angular velocity is proportional to the magnitude (amplitude) of the vibration of the mass body in the y-direction, the rate gyroscope can detect an angular velocity around the z-direction by measuring the amplitude of the vibration in the y-direction. The rate gyroscope is configured to calculate the rotation angle based on the detected angular velocity. Specifically, the rate gyroscope calculates the rotation angle by integrating the detected angular velocity with time. Here, there are bias error and drift error inevitably when detecting for example, an angular velocity. However, if the angular velocity is integrated to calculate a rotation angle, at the same time, the bias error and the drift error accompanying the angular velocity are also integrated and these errors are amplified. That is, the rate gyroscope is configured to detect the angular velocity and integrate the angular velocity with time to calculate the rotation angle. As a result, the bias error and the drift error accompanying the angular velocity are also integrated and the error is increased. From this, it is difficult to apply the rate gyroscope to the navigation in which the integration time becomes longer, in particular. In other words, for a gyroscope used for navigation and other applications where the integration time becomes longer, it is desired that the error is smaller than the rate gyroscope.

In this regard, there is a gyroscope called a rate integrating gyroscope as a vibration gyroscope. The principle of the rate integrating gyroscope is the same as that of Foucault pendulum. In the rate integrating gyroscope, the mass body vibrating in the opposite direction performs precession in proportion to the applied angular velocity. Therefore, the speed and position in the two axes of the mass body is known which makes it possible to know the angle of rotation. As a result, in the rate integrating gyroscope, even if there is a measurement error of the rotation angle, the measurement error is not integrated and amplified. Therefore, the rate integrating gyroscope can improve the detection accuracy of the rotation angle as compared with the rate gyroscope.

Thus, in Embodiment 1, by directly measuring a rotation angle, a study on further improving the performance of a rate integrating gyroscope is made, on the premise of the rate integrating gyroscope in which detection accuracy of a rotation angle can toe improved. Hereinafter, the technical idea of Embodiment 1 which has been studied will be described.

### Planar Configuration of Sensor Element in Embodiment 1

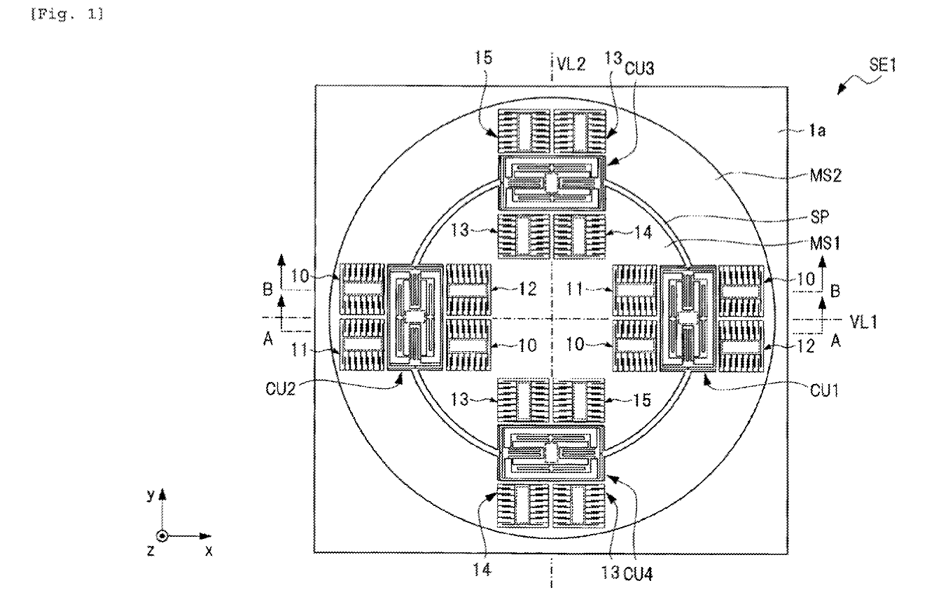

FIG. 1 is a diagram illustrating a planar configuration of a sensor element SE1 constituting a gyroscope in Embodiment 1. As illustrated in FIG. 1, the sensor element SE1 in Embodiment 1 has a substrate layer 1a, and a mass body MS1 and a mass body MS2 which are disposed in a floating state from the substrate layer 1a. The planar shape of the mass body MS1 is a disk shape, and the mass body MS2 having a concentric circular shape in plan view is disposed so as to surround the mass body MS1. That, is, the mass body MS2 is provided outside the mass body MS1. In other words, the mass body MS1 is provided inside the mass body MS2.

A gap SP is provided between the mass body MS1 and the mass body MS2, and the mass body MS1 and the mass body MS2 are mechanically connected by connecting portions CU1 to CU4. In particular, in FIG. 1, the mass body MS1 and the mass body MS2 are mechanically connected by the connecting portions CU1 to CU4 such that the mass body MS1 is displaceable in both an x-direction and a y-direction orthogonal to the so-direct ion and the mass body MS2 is also displaceable in both the x-direction and the y-direction. That is, the sensor element SE1 in Embodiment 1 includes the mass body MS1 displaceable in the x-direction and the y-direction orthogonal to the x-direction, the mass body MS2 displaceable in the x-direction and the y-direction, and connecting portions CU1 to CU4 provided between the mass body MS1 and the mass body MS2 and connecting the mass body MS1 and the mass body MS2.

At this time, in the sensor element SE1 in Embodiment 1, the mass of the mass body MS1 and the mass of the mass body MS2 are equal to each other. Further, in the sensor element SE1 in Embodiment 1, the mass body MS1 and the mass body MS2 are disposed such that the center of the mass body MS1 coincides with the center of the mass body MS2 as illustrated in FIG. 1.

As illustrated in FIG. 1, in the sensor element SE1 in Embodiment 1, the mass body MS1 and the mass body MS2 are mechanically connected by four connecting portions (unit connecting portions) CU1 to CU4 having the same structure. In particular, as illustrated in FIG. 1, the connecting portion CU1 out of the four connecting portions CU1 to CU4 is disposed on an imaginary line VL1 passing through the center of the mass body MS1 and extending in the x-direction, and the collecting portion CU2 out of the four connecting portions CU1 to CU4 is disposed on an imaginary line VL1 at a position symmetrical to the connecting portion CU1 with respect to the center of the mass body MS1. On the other hand, as illustrated in FIG. 1, the connecting portion CU3 out of the four connecting portions CU1 to CU4 is disposed on an imaginary line VL2 passing through the center of the mass body MS1 and extending in the y-direction, and the connecting portion CU4 out of the four connecting portions CU1 to CU4 is disposed on the imaginary line VL2 at a position symmetrical to the connecting portion CU3 with respect to the center of the mass body MS1.

The arrangement direction of the connecting portion CU1 and the arrangement direction of the connecting portion CU2 are the same, and the arrangement direction of the connecting portion CU3 and the arrangement direction of the connecting portion CU4 are the same. On the other hand, the arrangement direction of the connecting portion CU1 and the arrangement direction of the connecting portion CU3 differ by 90 degrees, and the arrangement direction of the connecting portion CU2 and the arrangement direction of the connecting portion CU4 are different by 90 degrees. That is, the connecting portion CU2 is disposed at a position where the connecting portion CU1 is rotated counterclockwise by 90 degrees with respect to the center of the mass body MS1, the connecting portion CU3 is disposed at a position where the connecting portion CU2 is rotated counterclockwise by 90 degrees with respect to the center of the mass body MS1, and the connecting portion CU4 is disposed at a position where the connecting portion CU3 is rotated counterclockwise by 90 degrees with respect to the center of the mass body MS1.

Subsequently, in the sensor element SE1 in Embodiment 1, a plurality of capacitive elements are formed inside the mess body MS, and a plurality of capacitive elements are also formed inside the mass body MS2, as illustrated in FIG. 1. Specifically, as illustrated in FIG. 1, a capacitive element functioning as a vibration driving unit 10 and a capacitive element functioning as a monitor portion 11 are formed at positions adjacent to the connecting portion CU1 inside the mass body MS1. Further, as illustrated in FIG. 1, a capacitive element functioning as a vibration driving unit 10 and a capacitive element functioning as a monitor portion 12 are formed at positions adjacent to the connecting portion CU2 inside the mass body MS1.

Further, as illustrated in FIG. 1, a capacitive functioning as a vibration driving unit 13 and a capacitive element functioning as a monitor portion 14 are formed at positions adjacent to the connecting portion CU3 inside the mass body MS1. Further, as illustrated in FIG. 1, a capacitive element functioning as a vibration driving unit 13 and a capacitive element functioning as a monitor portion 15 are formed at positions adjacent to the connecting portion CU4 inside the mass body MS1.

Further, as illustrated in FIG. 1, a capacitive element functioning as a vibration driving unit 10 and a capacitive element functioning as a monitor portion 12 are formed at positions adjacent to the connecting portion CU1 inside the mass body MS2. Further, as illustrated in FIG. 1, a capacitive element functioning as a vibration driving unit 10 and a capacitive element functioning as a monitor portion 11 are formed at positions adjacent to the connecting portion CU2 inside the mass body MS2.

Similarly, as illustrated in FIG. 1, a capacitive element functioning as a vibration driving unit 13 and a capacitive element functioning as a monitor portion 15 are formed at positions adjacent to the connecting portion CU3 inside the mass body MS2. Further, as illustrated in FIG. 1, a capacitive element functioning as a vibration driving unit 13 and a capacitive element functioning as a monitor portion 14 are formed at positions adjacent to the connecting portion CU4 inside the mass body MS2.

As described above, the sensor element SE1 of the gyroscope in Embodiment 1 has a planar configuration.

### Cross-Sectional Configuration of Sensor Element in Embodiment 1

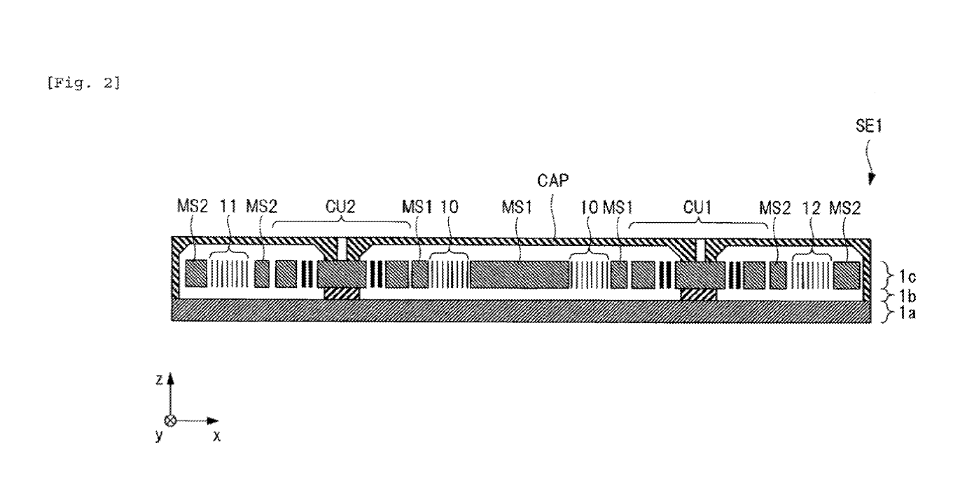

Next, a cross-sectional configuration of the sensor element SEX of the gyroscope in Embodiment 1. FIG. 2 is a cross-sectional view taken along line A-A of FIG. 1. As illustrated in FIG. 2, the sensor element SE1 in Embodiment 1 has a Silicon On Insulator (SOI) substrate having a substrate layer 1a, an insulating layer 1b, and a device layer 1c. As illustrated in FIG. 2, the insulating layer 1b is removed except for a portion connected to a part (fixing portion) of the connecting portion CU1 and a part (fixing portion) of the connecting portion CU2. Therefore, the device layer 1c has a structure floating from the substrate layer 1a, and the mass body MS1, the mass body MS2, the connecting portion CU1, the connecting portion CU2, the vibration driving unit 10, the monitor portion 11, and the monitor portion 12 are formed on the device layer 1c. Specifically, as illustrated in FIG. 2, the vibration driving unit 10 is formed inside the mass body MS1, the connecting portion CU1 is disposed outside the vibration driving unit 10 on the right side, and the mass body MS2 is disposed outside the connecting portion CU1. The monitor portion 12 is formed inside the mass body MS2 disposed outside the connecting portion CU1. On the other hand, the connecting portion CU2 is disposed outside the vibration driving unit 10 on the left side, and the mass body MS2 is disposed outside the connecting portion CU2. The monitor portion 11 is formed inside the mass body MS2 disposed outside the connecting portion CU2. Such a device layer 1c is processed by using for example, a photolithography technique and an etching technique, and the insulating layer 1b is also processed by the etching technique. Then, as illustrated in FIG. 2, a cap CAP is provided so as to cover the processed device layer 1c, and the processed device layer 1c is disposed in a sealed space interposed between the cap CAP and the substrate layer 1a. The pressure of the sealed space is set to a degree of vacuum at which energy loss due to damping is sufficiently suppressed.

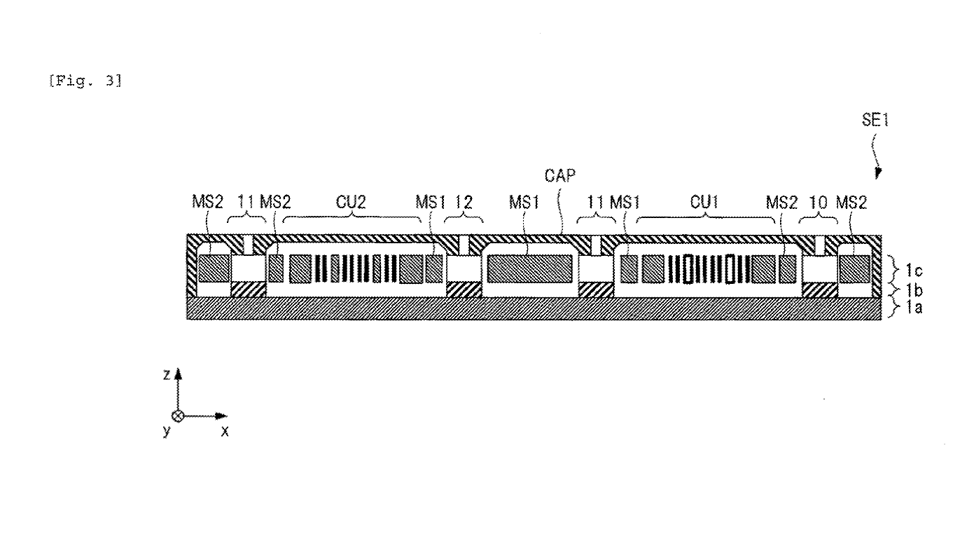

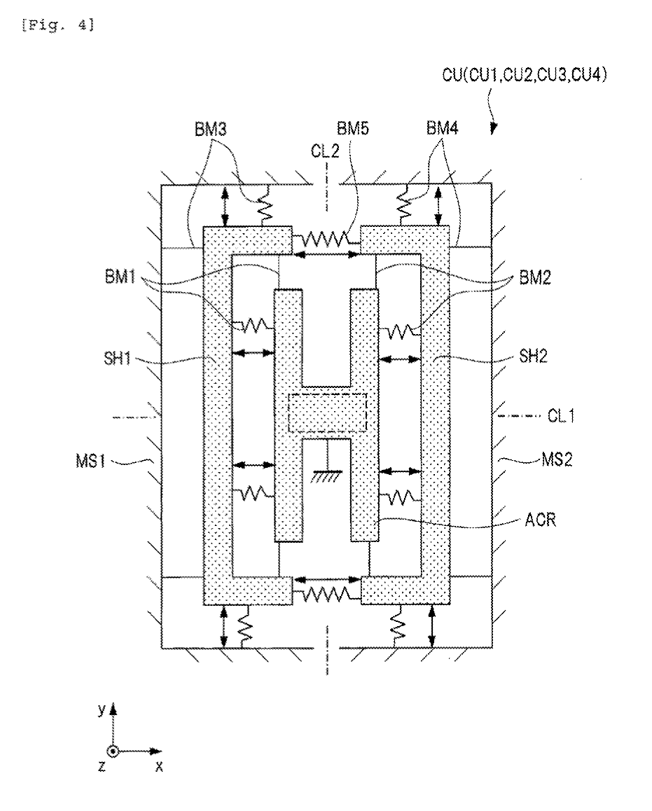

FIG. 3 is a cross-sectional view taken along line B-B of FIG. 1. As illustrated in FIG. 3, the sensor element SE1 in Embodiment 1 has a SOI substrate including a substrate layer 1a, an insulating layer 1b, and a device layer 1c. Then, as illustrated in FIG. 3, the insulating layer 1b is removed excluding parts connected to a part (fixed electrode) of the vibration driving unit 10, a part (fixed electrode) of the monitor portion 11, and a part (fixed electrode) of the monitor portion 12. Therefore, the device layer 1c has a structure floating from the substrate layer 1a, and the mass body MS1, the mass body MS2, the connecting portion CU1, the connecting portion CU2, the vibration driving unit 10, the monitor portion 11, and the monitor portion 12 are formed on the device layer 1c. Specifically, as illustrated in FIG. 3, the monitor portion 11 and the monitor portion 12 are formed inside the mass body MS1, the connecting portion CU1 is disposed outside the monitor portion 11, and the mass body MS2 is disposed outside the connecting portion CU1. The vibration driving unit 10 is formed inside the mass body MS2 disposed outside the connecting portion CU1. On the other hand, the connecting portion CU2 is disposed outside the monitor portion 12, and the mass body MS2 is disposed outside the connecting portion CU2. The vibration driving unit 10 is formed inside the mass body MS2 disposed outside the connecting portion CU2. Such a device layer 1c is processed by using for example, a photolithography technique and an etching technique, and the insulating layer 1b is also processed by the etching technique. Then, as illustrated in FIG. 3, a cap CAP is provided so as to cover the processed device layer 1c, and the processed device layer 1c is disposed in a sealed space interposed between the cap CAP and the substrate layer 1a. The pressure of the sealed space is set to a degree of vacuum at which energy loss due to damping is sufficiently suppressed.

As described above, the sensor element SE1 of the gyroscope in Embodiment 1 has a cross-sectional configuration.

<Configuration of Connecting Portion>

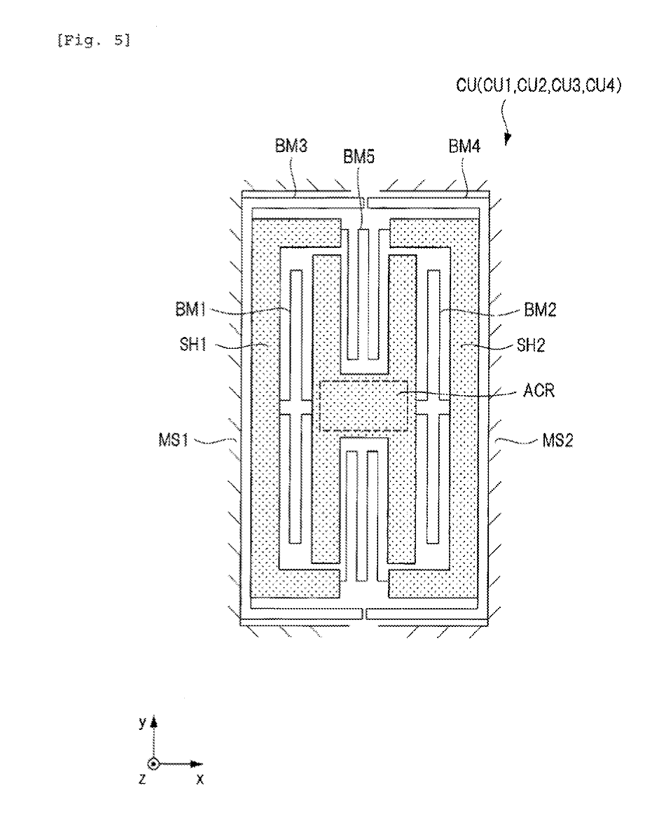

Next, the configuration of the connecting portions CU1 to CU4 will be described. Here, since each of the connecting portions CU1 to CU4 has the same structure, the connecting portions CU1 to CU4 will be described as the connecting portion CU. FIG. 4 is a schematic diagram illustrating the conceptual planar structure of the connecting portion CU in Embodiment 1. In FIG. 4, for example, a fixing portion ACR of an H shape is disposed in the central portion of the connecting portion CU, and a shuttle (first member) SH1 and a shuttle (second member) SH2 of a C shape are disposed so as to interpose the fixing portion ACR. The mass body MS1 is disposed outside the shuttle SH1, and the mass body MS2 is disposed, outside the shuttle SH2. Therefore, it can be said that the shuttle SH1 is disposed between the mass body MS1 and the fixing portion ACR, and that the shuttle SH2 is disposed between the mass body MS2 and the fixing portion ACR.

As illustrated in FIG. 4, the fixing portion ACR and the shuttle SH1 are mechanically connected by a beam BM1, and the fixing portion ACR and the shuttle SH2 are mechanically connected by a beam BM2. Further, the shuttle SH1 and the mass body MS1 are mechanically connected by a beam BM3, and the shuttle SH2 and the mass body MS2 and k are mechanically connected by a beam BM4. Further, the shuttle SH1 and the shuttle SH2 are mechanically connected by a beam BM5.

As described above, as illustrated in FIG. 4, the connecting portion CU in Embodiment 1 includes a fixing portion ACR fixed to the substrate, a shuttle SH1 provided between the fixing portion ACR and the mass body MS1, and a shuttle SH2 provided between the fixing portion ACR and the mass body MS2. As illustrated in FIG. 4, the connecting portion CU in Embodiment 1 includes a beam BM1 connecting the fixing portion ACR with the shuttle SH1, a beam BM2 connecting the fixing portion ACR with the shuttle SH2, a beam BM3 connecting the mass body MS1 with the shuttle SH1, a beam BM4 connecting the mass body MS2 with the shuttle SH2, and a beam BM5 connecting the shuttle SH1 with the shuttle SH2. At this time, a fixing portion ACR is provided between the shuttle SH1 and the shuttle SH2.

Subsequently, as illustrated in FIG. 4, the beam BM1 is configured to be soft in the x-direction and hard in the y-direction. That is, the beam BM1 is configured to be more flexible in the x-direction than the y-direction. Therefore, the beam BM1 is configured to be likely to be elastically deformed in the x-direction, but is unlikely to be elastically deformed in the y-direction. In order to express this, the connection in the x-direction is shown by a spring shape indicating that deformation is easy and the connection in the y-direction is shown by a straight line shape indicating that deformation is difficult, with respect to the beam BM1 illustrated in FIG. 4. As a result, the shuttle SH1 connected to the fixing portion ACR through the beam BM1 is configured to be displaceable only in the x-direction.

Similarly, as illustrated in FIG. 4, the beam BM2 is also configured to be soft in the x-direction and hard in the y-direction. That is, the beam BM2 is configured to be more flexible in the x-direction than the y-direction. Therefore, the beam BM2 is configured to be likely to be elastically deformed in the x-direction, but is unlikely to be elastically deformed in the y-direction. In order to express this, the connection in the x-direction is shown by a spring shape indicating that deformation is easy and the connection in the y-direction is shown by a straight line shape indicating that deformation is difficult, with respect to the beam BM2 illustrated in FIG. 4. As a result, the shuttle SH2 connected to the fixing portion ACR through the beam BM2 is also configured to be displaceable only in the x-direction.

Subsequently, as illustrated in FIG. 4, the beam BM3 is configured to be soft in the y-direction and hard in the x-direction. That is, the beam BM3 is configured to be more flexible in the y-direction than the x-direction. Therefore, the beam BM3 is configured to be likely to be elastically deformed in the y-direction and unlikely to be elastically deformed in the x-direction. In order to express this, the connection in the y-direction is shown by a spring shape indicating that deformation is easy and the connection in the x-direction is shown by a straight line shape indicating that deformation is difficult, with respect to the beam BM3 illustrated in FIG. 4. As a result, the mass body MS1 connected to the shuttle SH1 through the beam BM3 is displaceable in the y-direction despite the fact that the shuttle SH1 is not displaceable in the y-direction, and since the shuttle SH1 is displaceable in the x-direction, the mass body MS1 connected to the shuttle SH1 is also displaceable in the x-direction. That is, the mass body MS1 is configured to be displaceable in both the x-direction and the y-direction.

Similarly, as illustrated in FIG. 4, the beam BM4 is configured to be soft in the y-direction and hard in the x-direction. That is, the beam BM4 is configured to be more flexible in the y-direction than the x-direction. Therefore, the beam BM4 is configured to be likely to be elastic-ally deformed in the y-direction and unlikely to be elastically deformed in the x-direction. In order to express this, the connection in the y-direction is shown by a spring shape indicating that deformation is easy and the connection in the x-direction is shown by a straight line shape indicating that deformation is difficult, with respect to the beam BM4 illustrated in FIG. 4. As a result, the mass body MS2 connected to the shuttle SH2 through the beam BM4 is displaceable in fine y-direction despite the fact that the shuttle SH2 is not displaceable in the y-direction, and since the shuttle SH2 is displaceable in the x-direction, the mass body MS2 connected to the shuttle SH2 is also displaceable in the x-direction. That is, the mass body MS2 is configured to be displaceable in both the x-direction and the y-direction.

In addition, as illustrated in FIG. 4, the shuttle SH1 and the shuttle SH2 are mechanically connected by the beam BM5, and the beam BM is configured to be soft in the x-direction.

Based on the above, in the configuration of the connecting portion CU illustrated in FIG. 4, it is configured such that the shuttle SH1 and the shuttle SH2 are displaceable only in the x-direction, and the mass body MS1 and the mass body MS2 are displaceable in both the x-direction and the y-direction.

Subsequently, in the configuration of the connecting portion CU illustrated in FIG. 4, with respect to the center line CL1 passing through the center of the fixing portion ACR and extending in the x-direction, the shuttle SH1 has a symmetrical shape and the shuttle SH2 also has a symmetrical shape. Further, in the configuration of the connecting portion CU illustrated in FIG. 4, the shuttle SH1 and the shuttle SH2 are disposed symmetrically with respect to the center line CL2 passing through the center of the fixing portion ACR and extending in the y-direction. In this manner, the conceptual planar structure of the connecting portion CU in Embodiment 1 is configured.

A specific configuration example of the connecting portion CU will be described below. FIG. 5 is a plan view illustrating a specific configuration example of the connecting portion CU in Embodiment 1. As illustrated in FIG. 5, the connecting portion CU in Embodiment 1 includes a fixing portion ACR of an H shape disposed at the center position of the connecting portion CU, and the shuttle SH1 and the shuttle SH2 of a C shape disposed so as to sandwich this fixing portion ACR. For example, the fixing portion ACR and the shuttle SH1 are mechanically connected by a beam BM1. At this time, the beam BM1 is formed into a U shape having a size longer in the y-direction than in the x-direction and having a folded structure in the y-direction, whereby a beam configuration in which it is soft in the x-direction and hard in the y-direction has been realized, even in the beam BM1. Similarly, the fixing portion ACR and the shuttle SH2 are mechanically connected by a beam BM2. At this time, the beam BM2 is formed into a U shape having a size longer in the y-direction than in the x-direction and having a folded structure in the y-direction, whereby a beam configuration in which it is soft in the x-direction and hard in the y-direction has been realized, even in the beam BM2.

Next, as illustrated in FIG. 5, the shuttle SH1 and the mass body MS1 are mechanically connected by a beam BM3. At this time, the beam BM3 is formed into a U shape having a sloe longer in the x-direction than in the y-direction and having a folded structure in the x-direction, whereby a beam configuration in which it is soft in the y-direction and hard in the x-direction has been realized, even in the beam BM3. Similarly, the shuttle SH2 and the mass body MS2 are mechanically connected by a beam BM4. At this time, the beam BM4 is formed into a U shape having a size longer in the x-direction than in the y-direction and having a folded structure in the x-direction, whereby a beam configuration in which it is soft in the y-direction and hard in the x-direction has been realised, even in the beam BM4.

Further, as illustrated in FIG. 5, the shuttle SH1 and the shuttle SH2 are mechanically connected by a beam BM5. At this time, the beam BM5 is formed into a W shape having a size longer in the y-direction than in the x-direction and having a folded structure in the y-direction, whereby a beam configuration in which it is soft in the x-direction and hard in the y-direct ion has been realised, even in the beam BM5.

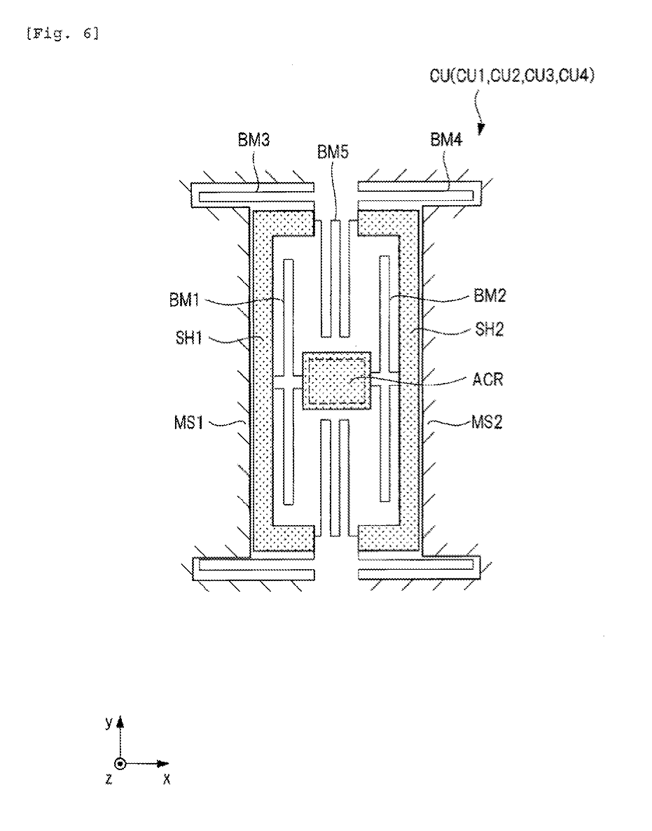

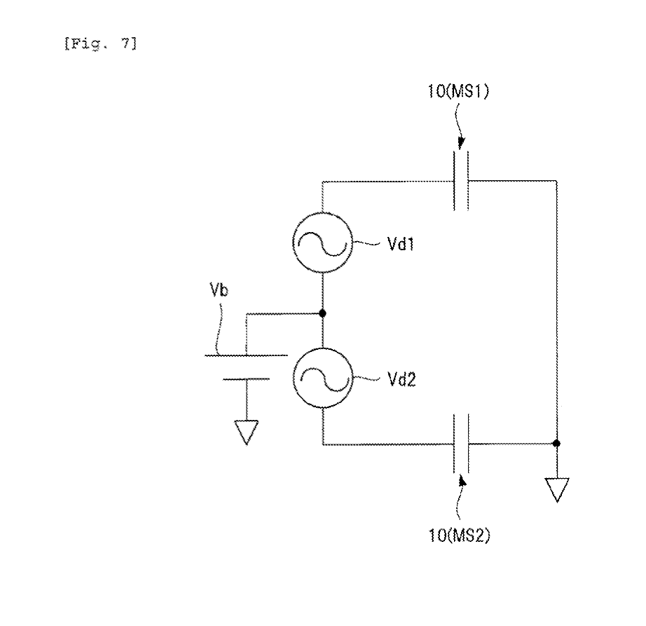

Subsequently, FIG. 6 is a plan view illustrating another specific configuration example of the connecting portion CU in Embodiment 1. The difference between the connecting portion CU illustrated in FIG. 5 and the connecting portion CU illustrated in FIG. 6 is that the planar shape of the fixing portion ACR disposed at the center position of the connecting portion CU illustrated in FIG. 5 is an H shape, while the planar shape of the fixing portion ACR disposed at the center position of the connecting portion CU illustrated in FIG. 6 is a rectangular shape. The other configuration of the connecting portion CU illustrated in FIG. 6 is substantially the same as that of the connecting portion CU illustrated in FIG. 5. According to the connecting portion CU illustrated in FIG. 6, the planar size of the fixing portion ACR is reduced, and as a result, the planar size of the entire connecting portion CU can be reduced. As described above, the structure illustrated in FIG. 5 and the structure illustrated in FIG. 6 can be adopted as the specific configuration of the connecting portion CU in Embodiment 1.

<Configuration of Vibration Driving Unit>

Next, the configuration of the vibration driving unit 10 shown in FIG. 1 will be described. In FIG. 1, the vibration driving unit 10 provided inside the mass body MS1 is provided to drive and vibrate the mass body MS1 in the x-direction, and the vibration driving unit 10 provided inside the mass body MS2 is provided to drive and vibrate the mass body MS2 in the x-direction. Similarly, in FIG. 1, the vibration driving unit 13 provided inside the mass body MS1 is provided to drive and vibrate the mass body MS1 in the y-direction, and the vibration driving unit 13 provided inside the mass body MS2 is provided to drive and vibrate the mass body MS2 in the y-direction. Here, since the vibration driving unit 10 and the vibration driving unit 13 have the same configuration except that the arrangement directions are different by 90 degrees, the vibration driving unit 10 will be explained.

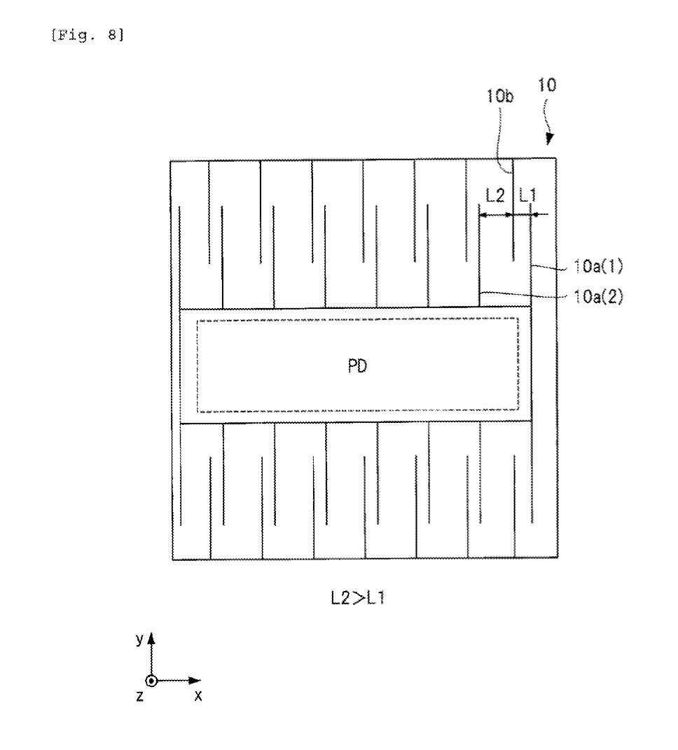

FIG. 7 illustrates a circuit configuration for driving and vibrating the mass body MS1 and the mass body MS2 using the vibration driving unit 10 in Embodiment 1. In the circuit configuration illustrated in FIG. 7, the mass body MS1 and the mass body MS2 are driven to vibrate in opposite phases (Out Of Phase). In FIG. 7, the mass body MS1 and the mass body MS2 are electrically grounded, and the DC power source Vb is connected to the vibration driving unit 10 formed inside the mass body MS1 and the vibration driving unit 10 formed inside the mass body MS2. At this time, the vibration driving unit 10 is configured with a capacitive element, one electrode (movable electrode) of the vibration driving unit 10 is electrically connected to GND and the other electrode (fixed electrode) of the vibration driving unit 10 is connected to the DC power source Vb.

Further, as illustrated in FIG. 7, an AC power source Vd1 is connected to the vibration driving unit 10 formed inside the mass body MS1, while an AC power source Vd2 is connected to the vibration driving unit 10 formed inside the mass body MS2. An electrostatic force based on the AC voltage supplied from the AC power source Vd1 is generated in the vibration driving unit 10 of the mass body MS1 configured with the capacitive element and an electrostatic force based on the AC voltage supplied from the AC power source Vd2 is generated in the vibration driving unit 10 of the mass body MS2 configured with the capacitive element. At this time, the AC voltage supplied from the AC power source Vd to the vibration driving unit 10 of the mass body MS1 and the AC voltage supplied from the AC power source Vd2 to the vibration driving unit 10 of the mass body MS2 have opposite phases (180 degrees phases are different). From this, the electrostatic force generated in the vibration driving unit 10 of the mass body MS1 and the electrostatic force generated in the vibration driving unit 10 of the mass body MS2 have direction opposite to each other. As a result, the mass body MS1 and the mass body MS2 vibrate in opposite phases.

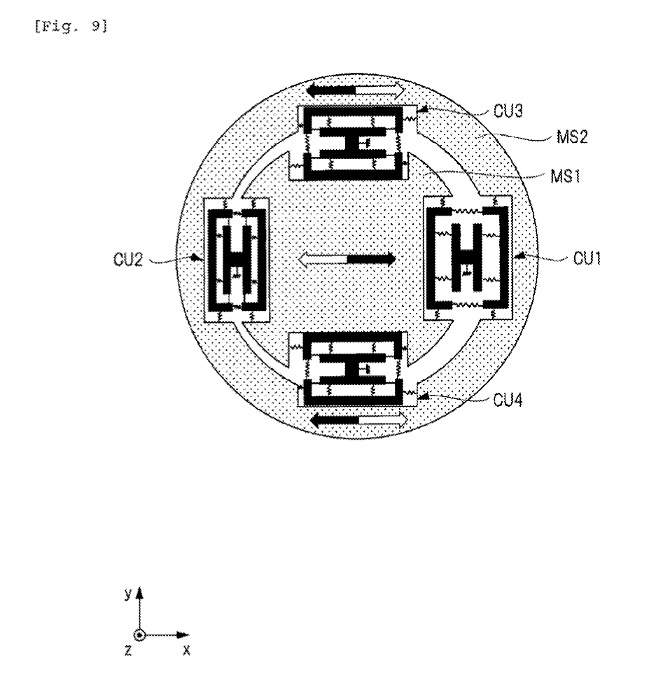

FIG. 8 is a schematic diagram illustrating a configuration example of the vibration driving unit 10. As illustrated in FIG. 8, the vibration driving unit 10 is configured with, for example, a capacitive element of a parallel structure. Specifically, the vibration driving unit 10 has a fixed electrode 10a(1) and a fixed electrode 10a(2) electrically connected to a pad PD functioning as a connection terminal to the outside, and a movable electrode 10b integrally formed with the mass body MS1 (mass body MS2) so as to be interposed between the fixed electrode 10a(1) and the fixed electrode 10a(2). At this time, for example, it is configured such that a distance L1 between the fixed electrode 10a(1) and the movable electrode 10b is different from a distance L2 between the fixed electrode 10a(2) and the movable electrode 10b. Specifically, the distance L1 is for example, about several μm, and the distance L2 is set to a value about three times the distance L1. In a case of configuring the vibration driving unit 10 with the capacitive element illustrated in FIG. 8, the distance L1 can be shortened, and as a result, the electrostatic force acting between the fixed electrode 10a(1) and the movable electrode 10b can be increased, thereby achieving high driving efficiency in the capacitive element.

In addition, as illustrated in FIG. 1, a monitor portion 11(12) that monitors the displacement (vibration) of the mass body MS1 in the x-direction is formed inside the mass body MS1, and a monitor portion 14 (15) that monitors the displacement (vibration) of the mass body MS1 in the y-direction is formed inside the mass body MS1. These monitor portions 11(12) and 14(15) are also configured with capacitive elements of the structure illustrated in FIG. 8. Similarly, as illustrated in FIG. 1, a monitor portion 11(12) that monitors the displacement (vibration) of the mass body MS2 in the x-direction is formed inside the mass body MS2, and a monitor portion 14(15) that monitors the displacement (vibration) of the mass body MS2 in the y-direction is formed inside the mass body MS2. These monitor portions 11(12) and 14(15) are also configured with capacitive elements of the structure illustrated in FIG. 8. That is, the monitor portion 11 (12) is configured with, for example, a capacitive element of a structure illustrated in FIG. 8, in order to detect the displacement (vibration) in the x-direction of the mass body MS1 or the mass body MS2 a change in an electrostatic capacitance value. Similarly, the monitor portion 14(15) is configured with, for example, a capacitive element of a structure illustrated in FIG. 8, in order to detect the displacement (vibration) in the y-direction of the mass body MS1 or the mass body MS2 as a change in an electrostatic capacitance value.

Therefore, the vibration driving unit 10 (13) and the monitor portions 11 (12) and 11 (15) are configured with capacitive elements having the structure illustrated in FIG. 3, but the usage is different. That is, in the vibration driving unit 10 (13), capacitive elements are used to generate an electrostatic force between the electrodes to drive and vibrate the mass body MS1 or the mass body MS2, whereas in the monitor portions 11 (12) and 14 (15), capacitive elements are used to obtain the displacement (vibration) of the mass body MS1 or the mass body MS2 as a change in electrostatic capacity and to monitor them.

### Operation of Sensor Element in Embodiment 1

The sensor element SE1 in Embodiment 1 is configured as described above, and the operation of the sensor element SE1 will be described below with reference to the drawings.

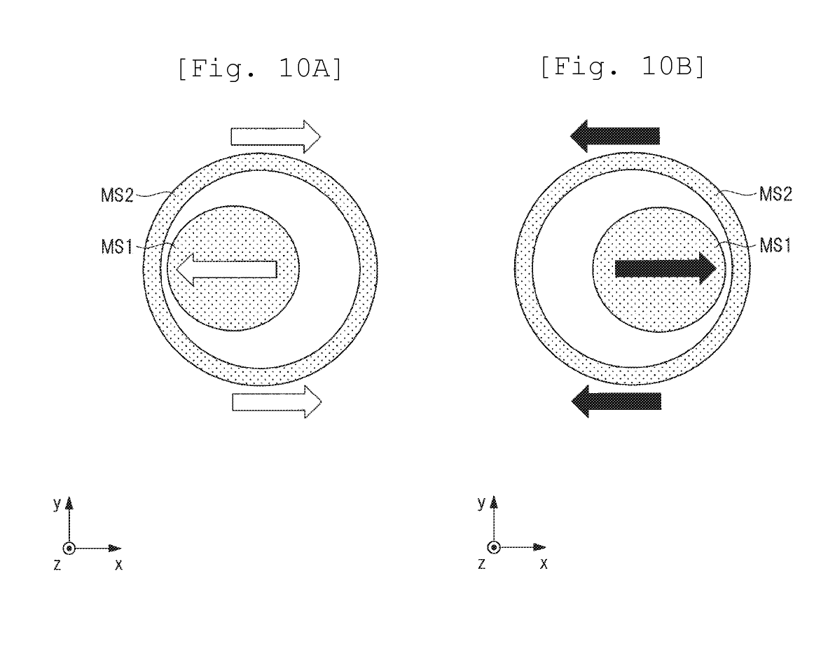

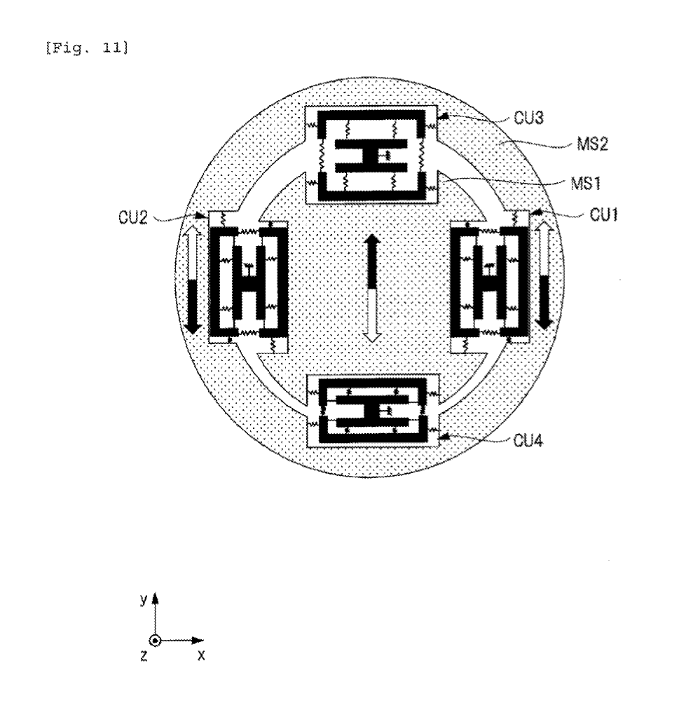

FIG. 9 is a diagram illustrating a state in which the mass body MS1 and the mass body MS2 connected by the connecting portions CU1 to CU4 are driven to vibrate in the x-direction. Since the mass body MS1 is displaceable in the x-direction, the mass body MS1 is driven to vibrate in the x-direction by the vibration driving unit 10 formed inside the mass body MS1 illustrated in FIG. 1. Similarly, since the mass body MS2 is displaceable in the x-direction, the mass body MS2 is driven to vibrate in the x-direction by the vibration driving unit 10 formed inside the mass body MS2 illustrated in FIG. 1. In particular, FIG. 10(a) and FIG. 10(b) are drawings schematically illustrating a state in which the mass body MS1 and the mass body MS2 are driven to vibrate in opposite phases in the x-direction. That is, as illustrated in FIG. 10(a), in a case where the mass body MS1 is displaced in the −x-direction, the mass body MS2 is displaced in the +x-direction. On the other hand, as illustrated in FIG. 10(b), in a case where the mass body MS1 is displaced in the +x-direction, the mass body MS2 is displaced in the −x-direction. In this way, in Embodiment 1, a tuning fork structure is formed in the x-direction by the mass body MS1 and the mass body MS2 connected by the connecting portions CU1 to CU4, and an operation in which the mass body MS1 and the mass body MS are driven to vibrate in opposite phases in the x-direction is realized by the deformation of the connecting portions CU1 to CU4.

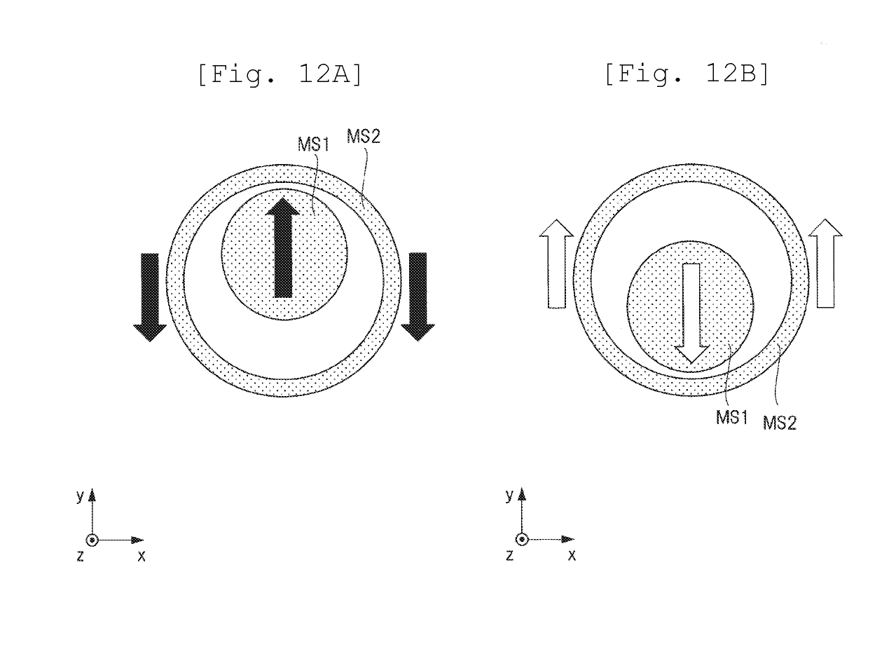

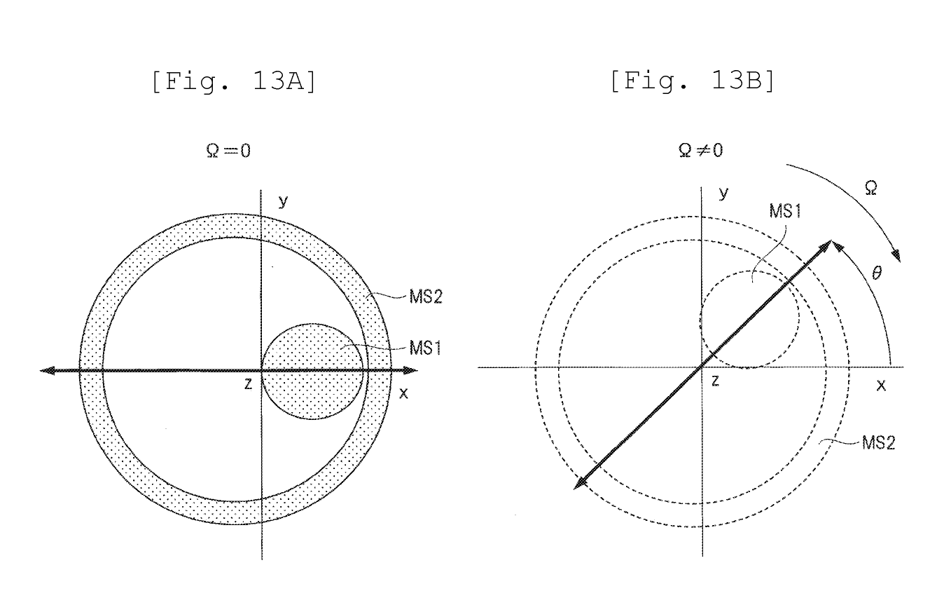

FIG. 11 is a diagram illustrating a state in which the mass body MS1 and the mass body MS2 connected by the connecting portions CU1 to CU4 are driven to vibrate in the y-direction. Since the mass body MS1 is displaceable in the y-direction, the mass body MS1 is driven to vibrate in the y-direction by the vibration driving unit 13 formed inside the mass body MS1 illustrated in FIG. 1. Similarly, since the mass body MS2 is displaceable in the y-direction, the mass body MS2 is driven to vibrate in the y-direction by the vibration driving unit 13 formed inside the mass body MS2 illustrated in FIG. 1. In particular, FIGS. 12(a) and FIG. 12(b) are drawings schematically illustrating a state in which the mass body MS1 and the mass body MS2 are driven to vibrate in opposite phases in the y-direction. That is, as illustrated in FIG. 12(a), in a case where the mass body MS1 is displaced in the +y-direction, the mass body MS2 is displaced in the −y-direction. On the other hand, as illustrated in FIG. 12(b), in a case where the mass body MS1 is displaced in the −y-direction, the mass body MS2 is displaced in the +y-direction. In this way, in Embodiment 1, a tuning fork structure is formed in the y-direction by the mass body MS1 and the mass body MS2 connected by the connecting portions CU1 to CU4, and an operation in which the mass body MS1 and the mass body MS2 are driven to vibrate in opposite phases in the y-direction is realized by the deformation of the connecting portions CU1 to CU4.

From the above, according to Embodiment 1, the mass body MS1 and the mass body MS2 are driven to vibrate in the x-direction by the vibration driving unit 10 and the mass body MS1 and the mass body MS2 can be driven to vibrate in the y-direction by the vibration driving unit 13. Therefore, according to Embodiment 1, by combining the vibration driving unit 10 and the vibration driving unit 13, the mass body MS1 and the mass body MS2 can be driven to vibrate in an arbitrary direction.

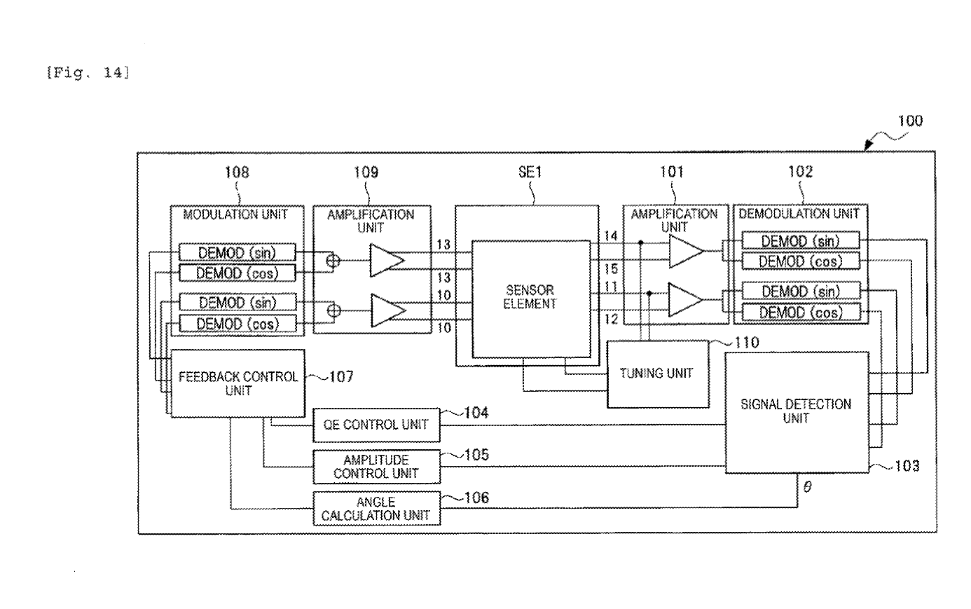

FIG. 13 is a schematic diagram for explaining the operation of a sensor element of Embodiment 1 in a case where angular velocity is applied around z-direction (clockwise). First, FIG. 13(a) illustrates an example of a state in which an angular velocity is not applied around the z-direction. Specifically, in FIG. 13(a), the mass body MS1 and the mass body MS2 are driven to vibrate in the x-direction. In this stats, as illustrated in FIG. 13(b), when an angular velocity (Ω) is applied around the z-direction (clockwise), Coriolis force causes the driven vibration in the x-direction to rotate counterclockwise (“Principle of a Foucault pendulum principle). By measuring the slope of this driven vibration, it is possible to measure the rotation angle θ caused by the angular velocity (Ω).

In this case, even in a case where the driven vibration rotates count or clockwise, it is important to maintain the amplitude of the driven vibration constant without hindering the rotation, from the viewpoint of Improving the detection accuracy of the rotation angle. In this regard, in Embodiment 1, as described above, the mass body MS1 and the mass body MS2 are driven to vibrate in the x-direction by the vibration driving unit 10 and the mass body MS1 and the mass body MS2 can be driven to vibrate in the y-direction by the vibration driving unit 13. From this, according to Embodiment 1, by controlling the vibration driving unit 10 and the vibration driving unit 13 in combination, even if the direction of the driven vibration of the mass body MS1 and the mass body MS2 is changed, it is possible to calculate the rotation angle while constantly controlling the amplitude of the driven vibration, by “the principle of the Foucault pendulum”. The control operation will be described below.

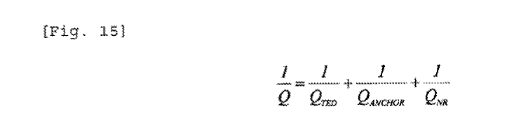

FIG. 14 is a diagram illustrating a configuration of the sensor system 100 in Embodiment 1. As illustrated in FIG. 14, the sensor system 100 in Embodiment 1 includes a sensor element SE1 which is a gyroscope, an amplification unit 101, a demodulation unit 102, a signal detection unit 103, a Quadrature Error (QE) control unit 104, an amplitude control unit 105, an angle calculation unit 106, a feedback control unit 107, a modulation unit 108, an amplification unit 109, and a tuning unit 110.

First, in the sensor element SE1 illustrated in FIG. 1, the displacement in the x-direction of the mass body MS1 is detected by the monitor portion 11 as a change in the electrostatic capacitance value, and the displacement in the x-direction of the mass body MS2 is detected by the monitor portion 12 as a change in the electrostatic capacitance value. On the other hand, the displacement in the y-direction of the mass body MS1 is detected by the monitor portion 14 as a change in the electrostatic capacitance value, and the displacement in the y-direction of the mass body MS2 is detected by the monitor portion 15 as a change in the electrostatic capacitance value. Then, the change in the electrostatic capacitance values of the monitor portion 11 and the monitor portion 12 is converted into a first voltage signal (X) by a C/V conversion unit (not illustrated). Similarly, the change in the electrostatic capacitance values of the monitor portion 14 and the monitor portion 15 is converted into a first voltage signal (Y) by the C/V conversion unit (not illustrated).

Next, as illustrated in FIG. 14, in the amplification unit 101, the first voltage signal (X) and the first voltage signal (Y) are respectively amplified, demodulated by the demodulation unit 102, and separated into components orthogonal to each other. In the tuning unit 110, matching between the resonance frequency in the x-direction and the resonance frequency in the y-direction is performed using a capacities- element (not illustrated).

Subsequently, the signal detection unit 103 acquires “Quadrature” (a component of a phase orthogonal to the driven vibration), “amplitude” (amplitude of the driven vibration) and “angle” which are useful parameters, from the signal demodulated by the demodulation unit 102. Then, in the QE control unit 104, compensation of “Quadrature” is performed. Further, the amplitude control unit 105 performs control so as to obtain a uniform amplitude. Further, the angle calculation unit 106 calculates a rotation angle. Thereafter, the feedback control unit 107 generates a feedback signal, based on the signals supplied from the QE control unit 104, the amplitude control unit 105, and the angle calculation unit 106. Next, the feedback signal generated by the feedback control unit 107 is modulated by the modulation unit 108, amplified by the amplification unit 109, and supplied to the vibration driving unit 10 and the vibration driving unit 13 without hindering the rotation angle. From this fact, according to the sensor system 100 in Embodiment 1, by controlling the vibration driving unit 10 and the vibration driving unit 13 in combination, even if the direction of the driving vibration of the mass body MS1 and the mass body MS2 is changed, it is possible to realize the operation of calculating the rotation angle while constantly controlling the amplitude of the driving vibration, by “Principle of a Foucault pendulum”.

### Features in Embodiment 1

Subsequently, features of Embodiment 1 will be described.

(1) Study on Increasing Q Value

In Embodiment 1, the Q value is focused, in order to improve the performance of a gyroscope. That is, the high Q value contributes to the reduction of the error. For example, the Q value in the gyroscope is an index illustrating the dissipation of energy from the gyroscope. Specifically, the Q value of the ideal “Foucault pendulum” is infinite. In other words, the fact that the Q value is infinite means that the energy dissipation is zero, which means that in the ideal “Foucault pendulum”, the vibration of the pendulum is not attenuated. That is, in the ideal “Foucault pendulum”, the consistency of the vibration of the pendulum is secured, so that it is possible to accurately detect the rotation angle based on the Coriolis force. On the other hand, in the actual gyroscope, since there is energy dissipation of a considerable amount, the driven vibration of the mass body decreases. This means that the Q value is reduced. Therefore, it is useful to increase the Q value of the gyroscope in order to maintain the driven vibration of the mass body constant and improve the accuracy of a rotation angle. Therefore, in Embodiment 1, since a study on increasing a Q value of a gyroscope is made, the study will be described below.

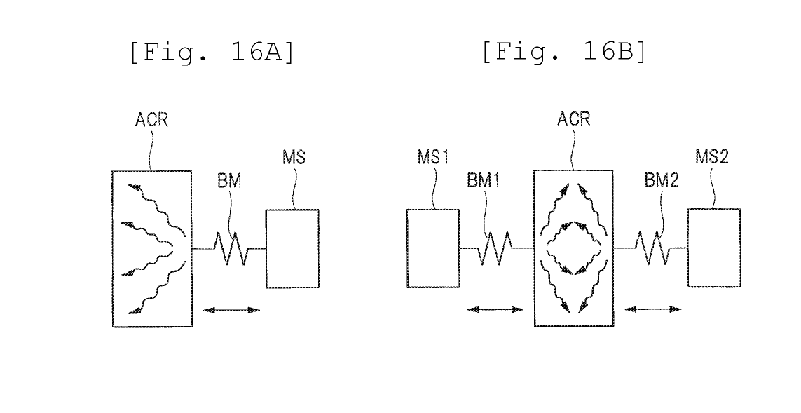

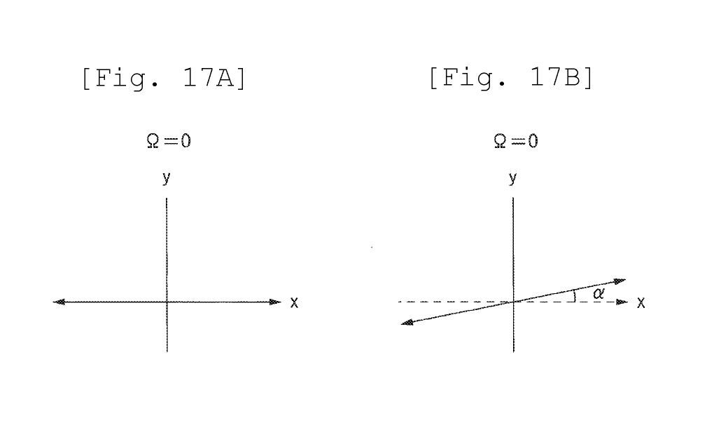

FIG. 15 is a relational expression illustrating the reciprocal (1/Q) of Q value in a gyroscope. As illustrated in FIG. 15, “1/Q” is expressed as “1/Q_{TED}”+“1/Q_{ANCHOR}”+“1/Q_{NP}”. Here, “1/Q_{TED}” indicates an index that elastic energy is converted into heat energy and dissipated, specifically, “1/Q_{TED}” is a term indicating dissipation of thermal energy generated by elastic deformation of a beam. On the other hand, “1/Q_{ANCHOR}” is a term indicating dissipation of vibration energy to the substrate in the fixing portion, and “1/Q_{NR}” is a term indicating dissipation (air damping) of energy due to resistance from the gas sealed in the sealed space.

First, in order to reduce the error, it is important to increase the consistency of the driven vibration of the mass body, and increasing the consistency of the driven vibration of the mass body means decreasing energy dissipation as much as possible. This is because increasing energy dissipation means that the driven vibration of the mass body is dampened. Therefore, reducing the error means suppressing energy dissipation, which corresponds to increasing the Q value. In other words, increasing the Q value means decreasing the reciprocal (1/Q) of the Q value. From this, it is important to reduce “1/Q_{TED}”, “1/Q_{ANCHOR}”, and “1/Q_{NP}” in order to reduce errors in the gyroscope.

Therefore, first, focusing on “1/Q_{NP}”, “1/Q_{NR}” indicates energy dissipation (air damping) due to resistance from gas sealed in a sealed space, so it is sufficient to reduce the amount of gas sealed in the sealed space. This is because if the amount of gas sealed in the sealed space is reduced the gas resistance applied to the mass body is reduced. Therefore, in order to reduce “1/Q_{NR}”, it is effective to reduce the pressure in the sealed space where the mass body is hermetically sealed. In particular, from the viewpoint of making “1/Q_{NR}” as small as possible, it is desirable to make the pressure of the sealed space close to the vacuum state.

Subsequently, “1/Q_{TED}” is focused. “1/Q_{TED}” is a terra indicating the dissipation of thermal energy generated by elastic deformation of a beam. In Embodiment 1, dissipation of thermal energy generated by elastic deformation of the beam is decreased by designing the shape of the beam (first feature point).

Next, “1/Q_{ANCHOR}” is focused “1/Q_{ANCHOR}” is a term indicating the dissipation of the vibration energy to the substrate in the fixing portion. In Embodiment 1, dissipation of the vibration energy to the substrate in the fixing portion is reduced by studying the arrangement of the fixing portion. This point will be described below.

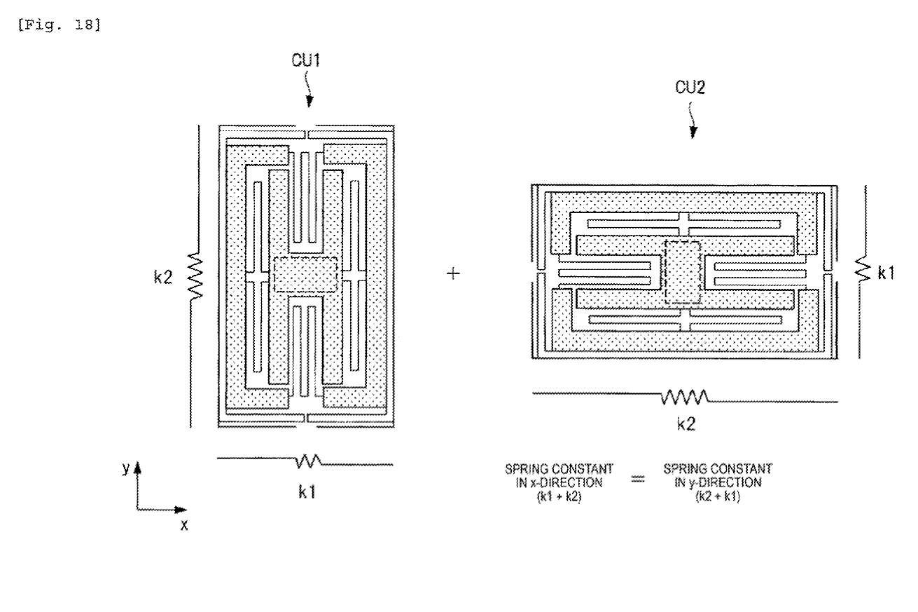

FIG. 16(a) is a schematic diagram illustrating a configuration in which a beam connected to the mass body is provided only on one side of the fixing portion, and FIG. 16(b) is a schematic diagram illustrating a beam connected to the mass body on both sides of the fixing portion. First, in FIG. 16(a), the fixing portion ACR and the mass body MS are connected by the beam BM. In this case, for example, acoustic energy generated by deformation of the beam BM is transmitted to the fixing portion ACR. Then, the acoustic energy transmitted to the fixing portion ACR is dissipated from the fixing portion ACR to the outside of the system. In other words, as illustrated in FIG. 16(a), in a configuration in which a beam connecting the mass body is provided only on one side of the fixing portion, dissipation of acoustic energy from the fixing portion ACR to the outside of the system increases, which means that “1/Q_{ANCHOR}” increases. On the other hand, in FIG. 16(b), beams connecting the mass bodies are provided on both sides of the fixing portion. Specifically, as illustrated in FIG. 16(b), the mass body MS1 is disposed on the left side of the fixing portion ACR and the mass body MS2 is disposed on the right side of the fixing portion ACE so as to sandwich the fixing portion ACR. The fixing portion ACR and the mass body MS1 are connected by a beam BM1, and the fixing portion ACR and the mass body MS2 are connected by a beam BM2. In this case, as illustrated in FIG. 16(b), the acoustic energy accompanying the elastic deformation of the beam BM1 is transmitted from the left side to the fixing portion ACR and the acoustic energy accompanying the elastic deformation of the beam BM2 is transmitted from the right side. As a result, in the configuration illustrated in FIG. 16(b), the acoustic energy is transmitted from the beam BM1 to the fixing portion ACR and the acoustic energy is transmitted from the beam BM1 to the fixing portion ACR. This means that the acoustic energy is canceled in the fixing portion ACR, which means that dissipation of acoustic energy to the outside of the system can be suppressed. In other words, as illustrated in FIG. 16(b), dissipation of acoustic energy to the outside of the system can be suppressed in a configuration of disposing the mass body MS1 and the mass body MS2 so as to sandwich the fixing portion ACR. Therefore, according to the configuration illustrated in FIG. 16(b), “1/Q_{ANCHOR}” can be reduced. Therefore, in Embodiment 1, for example, as illustrated in FIG. 5, it is configured such that the shuttle SH1 and the shuttle SH2 sandwich one fixing portion ACR, the shuttle SH1 and the fixing portion ACR are connected by the beam BM1, and the shuttle SH2 and the fixing portion ACR are connected by the beam BM2, (second feature point). Thus, according to the second feature point in Embodiment 1, dissipation of acoustic energy in the fixing portion can be reduced, thereby reducing “1/Q_{ANCHOR}”.

From the above, according to Embodiment 1, “1/Q_{TED}” can be reduced by the first feature point, and “1/Q_{ANCHOR}” can be reduced by the second feature point, so it is possible to reduce the reciprocal (1/Q) of the Q value by combining the first feature point and the second feature point. As a result, according to Embodiment 1, it is possible to reduce the error, thereby improving the performance of the gyroscope.

(2) Study on Reducing Erroneous Detection

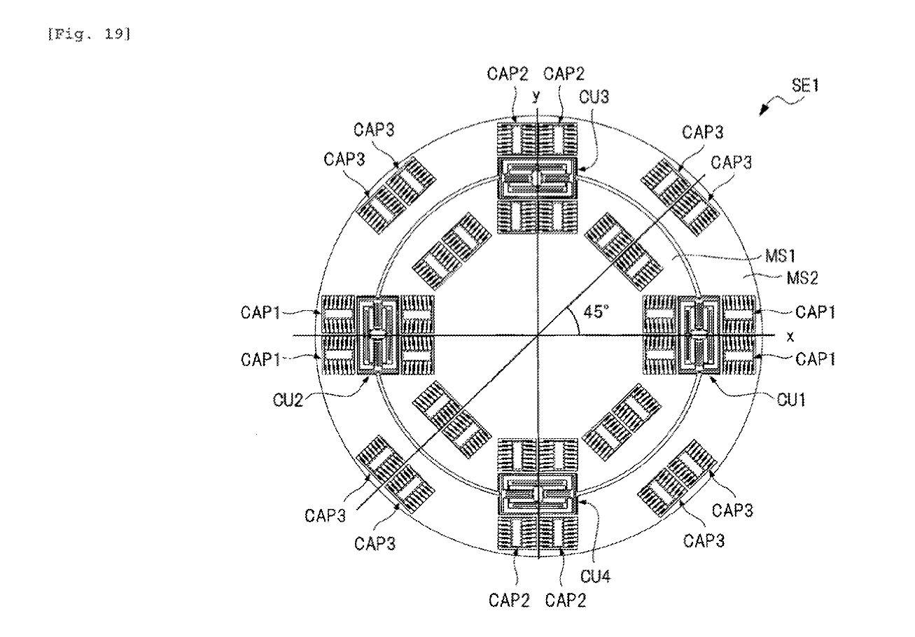

Subsequently, study on reducing erroneous detection will be described. First, erroneous detection sill be described with reference to FIG. 17. FIG. 17 is a diagram for explaining a mechanism of occurrence of erroneous detection. FIG. 17(a) is a diagram schematically illustrating ideal driven vibration in a case where an angular velocity is not applied, and FIG. 17(b) is a diagram schematically illustrating driven vibration in a state where erroneous detection occurs in a case where an angular velocity is not applied.

First, as illustrated in FIG. 17(a), the ideal driven vibration when the angular velocity is not applied is in a case where the mass body is driven to vibrate only in the x-direction. However, the mass body is configured to be displaceable not only in the x-direction but also in the y-direction. Therefore, even if it is tried to drive the mass body to vibrate only in the x-direction, actually, as illustrated in FIG. 17(b), due to coupling in the x-direction and the y-direction, slight vibration may occur in the y-direction, even in a state where an angular velocity is not applied. In this case, as illustrated in FIG. 17(b), the direction of the driven vibration of the mass body deviates front the x-direction by the angle α. Although the vibration in the y-direction is the cause of the erroneous detection and despite the fact that the angular velocity is not applied, there is an erroneous detection in which the direction of the driven vibration deviates from the x-direction by the angle α due to the Coriolis force caused by the application of the angular velocity.

Thus, in Embodiment 1, study on reducing the erroneous detection is made. Specifically, for example, as illustrated in FIG. 5, it is configured such that the fixing portion ACR is not directly connected to the mass body MS1 and the mass body MS2, and is connected thereto through the shuttle SH1 and the shuttle SH2. That is, in Embodiment 1, as illustrated in FIG. 5, the shuttle SH1 and the shuttle SH2 are disposed so as to sandwich the fixing portion ACR, and the mass body MS1 is disposed outside the shuttle SH1, and the mass body MS2 is disposed outside the shuttle SH2. The fixing portion ACR and the shuttle SH1 are connected by the beam BM1 softer in the x-direction than in the y-direction, and the fixing portion ACR and the shuttle SH2 are connected by the beam BM1 softer in the x-direction than in the y-direction. Further, the shuttle SH1 and the mass body MS1 are connected by the beam BM3 softer in the y-direction than in the x-direction, and the shuttle SH2 and mass body MS2 are connected by the beam BM3 softer in the y-direction than in the x-direction. As a result, according to Embodiment 1, the shuttle SH1 and the shuttle SH2 are configured to be displaceable only in the x-direction, and the mass body MS1 and the mass body MS2 are configured to be displaceable in both the x-direction and the y-direction. That is, in Embodiment 1, there is a feature point that the mass body MS1 and the mass body MS2 that are displaceable in both the x-direction and the y-direction are not directly connected to the fixing port ion ACR but are connected through the shuttle SH1 and the shuttle SH2 which are displaceable only in the x-direction (the third feature point). Thus, since it is possible to make the shuttle SH1 and the shuttle SH2 displaceable only in the x-direction, in a case where the mass body MS1 and the mass body MS2 are driven to vibrate in the x-direction, coupling in the x-direct ion and the y-direction is blocked (decoupling) by the shuttle SH1 and the shuttle SH2. As a result, according to Embodiment 1, erroneous detect ion in driven vibration of the mass body MS1 and the mass body MS2 can be reduced by providing the shuttle SH1 and the shuttle SH2. In other words, in Embodiment 1, it is configured such that a shuttle SH1 and a shuttle SH2 directly connected to the fixing portion ACR are provided and the shuttle SH1 and the shuttle SH2 are displaceable only in the x-direction, which reduces the cause of occurrence of erroneous detection. Therefore, according to the third feature point in Embodiment 1, despite the fact that an angular velocity is not applied, an erroneous detection hardly occurs that the direction of the driven vibration deviates by an angle α from the x-direction due to the Coriolis force caused by the application of the angular velocity, thereby improving the performance of the gyroscope.

(3) Study on Enhancing Symmetry

Next, a study on enhancing symmetry will be described. In Embodiment 1, the mass of the mass body MS1 and the mass of the mass body MS2 are made equal (fourth feature point). That is, in Embodiment 1, there is a symmetry in the mass body MS1 and the mass body MS2 with respect to mass. This is because making the mass of the mass body MS1 equal to the mass of the mass body MS2 means that the resonance frequency of the mass body MS1 is made equal to the resonance frequency of the mass body M32. In other words, making the resonance frequency of the mass body MS1 equal to the resonance frequency of the mass body MS2 is very important for maintaining the balance of the sensor system. Therefore, in Embodiment 1, the mass of the mass body MS1 and the mass of the mass body MS2 are made equal in order to make the resonance frequency of the mass body MS1 equal to the resonance frequency of the mass body MS2. In particular, in Embodiment 1, the mass body MS1 and the mass body MS2 are coupled through the shuttle SH1, the shuttle SH2, and the beam BM5 connecting the shuttle SH1 with the shuttle SH2, and this structure contributes to fixing the resonance frequency of the mass body MS1 and the resonance frequency of the mass body MS2 to equal values (the fifth feature point). Further, as illustrated in FIG. 4, a fact that the shuttle SH1 and the shuttle SH2 are disposed symmetrically with respect to the center line CL2, and a fact that the shuttle SH1 itself and the shuttle SH2 itself have a symmetrical structure with respect to the center line CL1 contribute to making the resonance frequency of the mass body MS1 equal to the resonance frequency of the mass body MS2 (the sixth feature point).

Therefore, according to Embodiment 1, the resonance frequency of the mass body MS1 and the resonance frequency of the mass body MS2 ran be made equal by the synergistic effect of the fourth feature point, the fifth feature point, and the sixth feature point. As a result, the following effects can be obtained.

For example, driven vibration is understood as mechanical wave motion (acoustic wave). The acoustic wave caused by the driven vibration of the mass body MS1 and the acoustic wave caused by the driven vibration of the mass body MS2 proceed toward the fixing portion ACR. At this time, in a case where the resonance frequency of the mass body MS1 is different from the resonance frequency of the mass body MS2, in the fixing portion ACR, the acoustic wave caused by the driven vibration of the mass body MS1 and the acoustic wave caused by the driven vibration of the mass body MS2 are not canceled, and the dissipation of energy from the fixing portion ACR occurs. In other words, in a case where the resonance frequency of the mass body MS1 is different from the resonance frequency of the mass body MS2, it is difficult to maintain the consistency of the driven vibration, which lowers the detection accuracy of the gyroscope. On the other hand, in a case where the resonance frequency of the mass body MS1 is equal to the resonance frequency of the mass body MS2, the acoustic wave caused by the driven vibration of the mass body MS1 and the acoustic wave caused by the driven vibration of the mass body MS2 are canceled in the fixing portion ACR. Therefore, in a case where the resonance frequency of the mass body MS1 is equal to the resonance frequency of the mass body MS2, the acoustic waves leaking from the fixing portion ACR can be reduced. This means that dissipation of energy from the fixing portion ACR can be suppressed, which means that the driven vibration of the mass body MS1 and the driven vibration of the mass body MS2 can be maintained constant. Therefore, according to the fourth feature point and the fifth feature point in Embodiment 1, the resonance frequency of the mass body MS1 is made equal to the resonance frequency of the mass body MS2. As a result, dissipation of energy from the fixing portion ACR can be suppressed, which can lower the detection error of the gyroscope.

Subsequently, in Embodiment 1, a study to be described later is made to further enhance symmetry. In particular, since increasing the symmetry in the x-direction and the symmetry in the y-direction is useful to reduce the detection error, in Embodiment 1, in order to increase the symmetry in the x-direction and the symmetry in the y-direction, the center of the mass body MS1 and the center of the mass body MS2 are made to coincide (seventh feature point).

For example, in a case where the gyroscope operates under the actual external environment in which there is external acceleration, it is affected by external acceleration. For example, assuming a tuning fork structure, in a case where the center (center of gravity) of the mass body MS1 and the center (center of gravity) of the mass body MS2 deviate, the external acceleration has different effects in the x-direction and the y-direction. Specifically, forces and torque are generated due to external acceleration. On the other hand, in a case where the center of the mass body MS1 coincides with the center of the mass body MS1, the forces and torques resulting from the external acceleration are canceled. As a result, according to the seventh feature point of Embodiment 1, if is possible to provide a gyroscope less susceptible to external acceleration.

Further, in Embodiment 1, in order to make the resonance frequency in the x-direction coincide with the resonance frequency in the y-direction, a study on enhancing the symmetry in the x-direction and the symmetry in the y-direction is made. Specifically, as illustrated in FIG. 1, in Embodiment 1, the mass body MS1 and the mass body MS2 are connected by four connecting portions CU1 to CU4. In particular, in Embodiment 1, the mass body MS1 and the mass body MS2 are connected, by using the connecting portions (the connecting portion CU1 and the connecting portion CU2, and the connecting portion CU3 and the connecting portion CU4) having the same structure with the arrangement directions different by 90 degrees (eighth feature point). Thus, according to Embodiment 1, the resonance frequency in the x-direction and the resonance frequency in the y-direction can be substantially made coincide with each other. The reason will be described below.

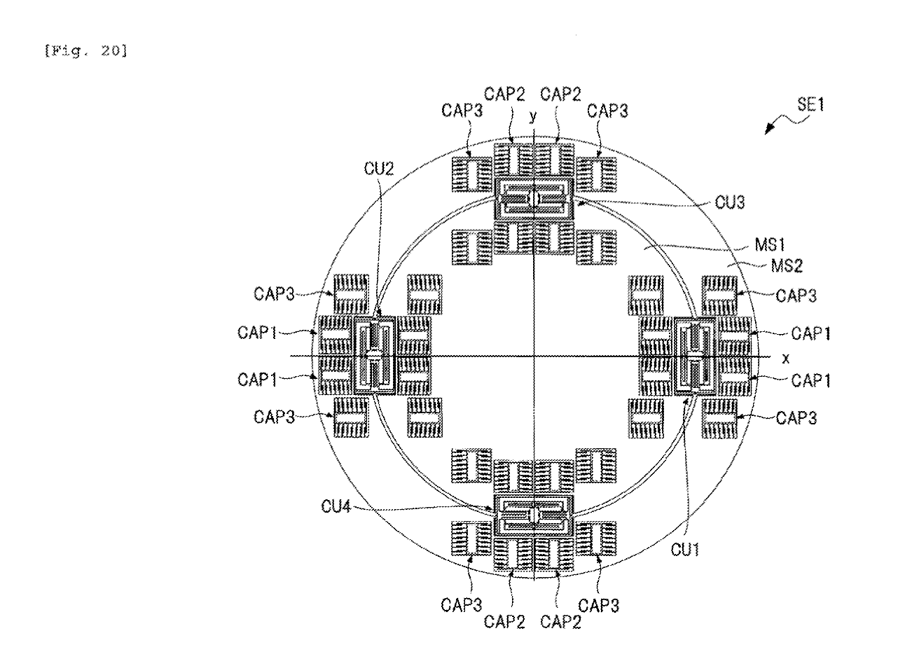

The resonance frequency depends on the spring constant (k) together with the mass (m) (f=1/2π×√(k/m.). Therefore, in order to make the resonance frequency in the x-direction coincide with the resonance frequency in the y-direction, it is useful to make the spring constants equal. Here, FIG. 18 is a diagram for explaining a concept of matching a spring constant in the x-directions and a spring constant in the y-direction. For example, as illustrated on the left side of FIG. 18, in general, the spring constant (k1) in the x-direction and the spring constant (k2) in the y-direction of the connecting portion CU1 adopted in Embodiment 1 are different from each other. Therefore, for example, in a case where the mass body MS1 and the mass body MS are connected by the connecting portion CU1, the spring constant in the x-direction and the spring constant in the y-direction are different from each other, so the resonance frequency in the x-direction and the resonance frequency in the y-direction are different from each other. Thus, in Embodiment 1, for example, as illustrated in FIG. 1, the mass body MS1 and the mass body MS2 are connected, by using the connecting portions (the connecting portion CU1 and the connecting portion CU2, and the connecting portion CU3 and the connecting portion CU4) having the same structure with the arrangement directions different by 90 degrees. In this case, as illustrated in FIG. 18, the spring constant in the x-direction of the connection structure of the mass body MS1 and the mass body MS2 is the combination of the spring constant (k1) in the x-direction of the connecting portion CU1 and the spring constant (k2) in the x-direction of the connecting portion CU2. Similarly, as illustrated in FIG. 18, the spring constant in the y-direction of the connection structure of the mass body MS1 and the mass body MS2 is the combination of the spring constant (k2) in the y-direction of the connecting portion CU1 and the spring constant (k1) in the y-direction of the connecting portion CU2. Therefore, focusing on the combination of the connecting portion CU1 and the connecting portion CU2 in which the arrangement directions are mutually different by 90 degrees, the spring constant (k1+k2) in the x-direction and the spring constant (k2+k1) in the y-direction are equal to each other. Considering that the mass of the mass body MS1 is equal to the mass of the mass body MS2, according to Embodiment 1, it is possible to substantially match the resonance frequency in the x-direction and the resonance frequency in the y-direction. As a result, according to Embodiment 1, the detection error of the gyroscope can be reduced.

(4) Study on Increasing Signal

Next, a study on increasing the signal will foe described. For example, in the sensor element SE1 in Embodiment 1, a plurality of capacitive elements are formed inside the mass body MS1, and a plurality of capacitive elements are formed inside the mass body MS2, as illustrated in FIG. 1 (the ninth feature point). Thus, according to Embodiment 1, the following effects can be obtained.

For example, it is conceivable to provide a capacitive element functioning as the vibration driving with unit 10 (13) and a capacitive element functioning as the monitor portions 11 (12) and 14 (15) inside the shuttle which is a constituent element of each of the connecting portions CU1 to CU4. However, in this configuration, since the difference size of the shuttle is small, the size (size of an electrode area) of the capacitive element formed inside the shuttle is also reduced. For example, this means that, in a case of focusing on the capacitive element functioning as the vibration driving unit 10 (13), the electrostatic force generated by the capacitive element is reduced. Therefore, in order to obtain large driving vibration, it is necessary to increase the voltage applied to the capacitive element, which means that the power consumption of the sensor increases. On the other hand, for example, in a case of focusing on the capacitive element functioning as the monitor portions 11 (12) and 14 (15), the fact that the size (the size of the electrode area) of the capacitive element is reduced means that the electrostatic capacitance value of the capacitive element is reduced. In this case, the change in the electrostatic capacitance value of the capacitive element is reduced, which means that the output signals from the monitor portions 11 (12) and 14 (15) are reduced.

In this regard, it is conceivable to increase the size of a shuttle, but if the size of the shuttle is increased, the size of each of the connecting portions CU1 to CU4 is increased, which hinders the miniaturization of a gyroscope.

Thus, in Embodiment 1, a plurality of capacitive elements are formed inside the mass body MS1, and a plurality of capacitive elements are formed inside the mass body MS2. In this case, since the size of the mass body MS1 and the size of the mass body MS2 are much larger than the size of the shuttle, the size of the capacitive element formed inside the mass body MS1 or the mass body MS2 cars be increased without increasing the size of the gyroscope. For example, this means that, in a case of focusing on the capacitive element functioning as the vibration driving unit 10 (13), it is possible to increase the electrostatic force generated by the capacitive element, even without increasing the voltage applied to the capacitive element. Therefore, according to the gyroscope in Embodiment 1, an increase in power consumption can be suppressed. On the other hand, for example, in a case of focusing on the capacitive element functioning as the monitor portions 11 (12) and 14 (15), the fact that the size (the size of the electrode area) of the capacitive element increases means that the electrostatic capacitance value of the capacitive element increases. In this case, the change in the electrostatic capacitance value of the capacitive element increases, which means that the output signals from the monitor portions 11 (12) and 14 (15) can be increased.

From the above, according to Embodiment 1, the error (noise) can be reduced by the first feature point to the eighth feature point described in (1) to (3). According to the ninth feature point described in (4), the signal can be increased. This means that the S/N ratio can be improved by the synergistic effect of the point that the error (noise) can be reduced and the point that the signal can be increased, according to the gyroscope in Embodiment 1, which makes it possible to improve the performance of the gyroscope.

### MODIFICATION EXAMPLE 1

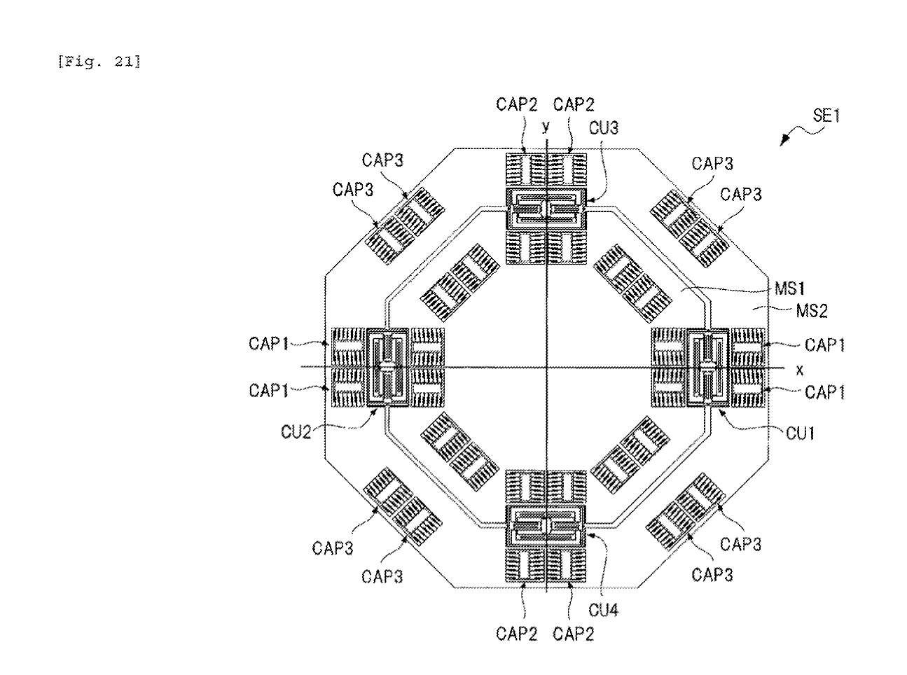

FIG. 19 is a plan view illustrating a configuration of a sensor element SE1 in Modification Example 1. As illustrated in FIG. 19, in the sensor element SE1 in Modification Example 1, a capacitive element CAP1 is disposed inside the mass body MS1 and inside the mass body MS2 in the vicinity of each of the connecting portion CU1 and the connecting portion CU2 disposed on the x-axis, and a capacitive element CAP2 is disposed inside the mass body MS1 and inside the mass body MS2 in the vicinity of each of the connecting portion CU3 and the connecting portion CU4 disposed on the y-axis. Further, in Modification Example 1, as illustrated in FIG. 19, the capacitive elements CAP3 are also disposed in the direction of 45 degrees from the x-axis and the direction of 135 degrees from the x-axis, respectively. From this, according to the sensor element SE1 in Modification Example 1, the number of capacitive elements functioning as the vibration driving unit and the monitor portion can be increased more than in Embodiment 1 illustrated in FIG. 1, so it is possible to improve the driving force in the vibration driving unit and the detection sensitivity in the monitor portion.

For example, in Modification Example 1 illustrated in FIG. 19, the capacitive element CAP1 is made to function as a vibration driving unit in the x-direction, the capacitive element CAP2 is made to function as the vibration driving unit in the y-direction, and the capacitive element CAP3 is made to function as a monitor portion.

### MODIFICATION EXAMPLE 2

FIG. 20 is a plan view illustrating a configuration of a sensor element SE1 in Modification Example 2. As illustrated in FIG. 20, in the sensor element SE1 in Modification Example 2, a capacitive element CAP1 is disposed inside the mass body MS1 and inside the mass body MS2 in the vicinity of each of the connecting portion CU1 and the connecting portion CU2 disposed on the x-axis, and a capacitive element CAP2 is disposed inside the mass body MS1 and inside the mass body MS2 in the vicinity of each of the connecting portion CU3 and the connecting portion CU4 disposed on the y-axis. Further, in Modification Example 2, a capacitive element CAP3 is disposed at a position adjacent to the capacitive element CAP1, and a capacitive element CAP3 is also disposed at a position adjacent to the capacitive element CAP2. Thus, also in the sensor element SE1 in Modification Example 2, the number of capacitive elements functioning as the vibration driving unit and the monitor portion can be increased, so it is possible to improve the driving force in the vibration driving unit and the detection sensitivity in the monitor portion.

### MODIFICATION EXAMPLE 3

FIG. 21 is a plan view illustrating a configuration of a sensor element SE1 in Modification Example 3. As illustrated in FIG. 21, in Modification Example 3, the outer shape of the mass body MS1 and the outer shape of the mass body MS2 are an octagonal shape. By adopting such a shape, as illustrated in FIG. 21, the area can be increased compared with the circular shape, and the electrode capacity can be increased and the inertia amount can be increased. In this way, the outer shape of the mass body MS1 and the outer shape of the mass body MS2 are not limited to the circular shape, but may be a polygonal shape represented by an octagonal shape.

### MODIFICATION EXAMPLE 4

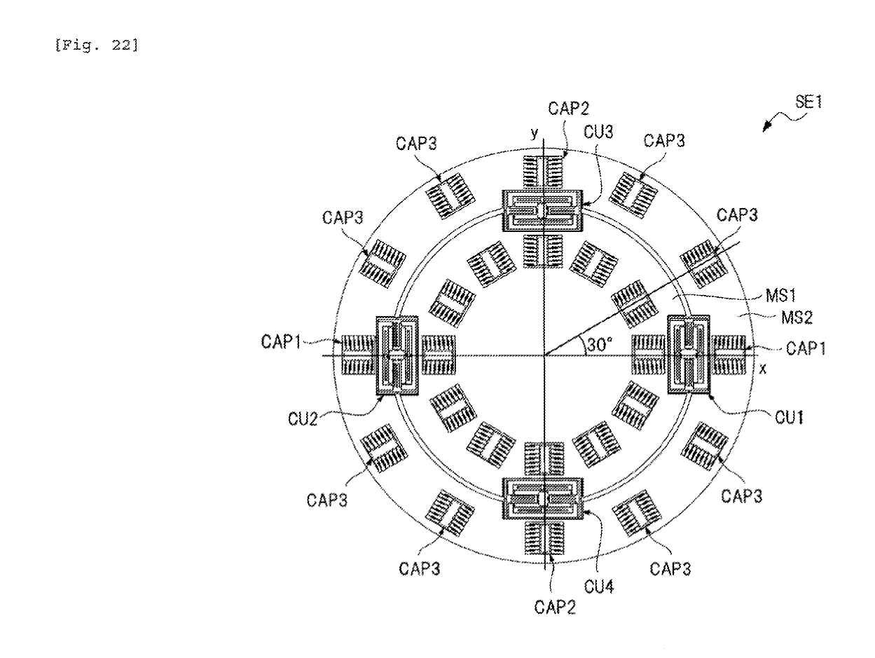

FIG. 22 is a plan view illustrating a configuration of a sensor element SE1 in Modification Example 4. As illustrated in FIG. 22, in the sensor element SE1 in Modification Example 4, a capacitive element CAP1 is disposed inside the mass body MS1 and inside the mass body MS2 in the vicinity of each of the connecting portion CU1 and the connecting portion CU2 disposed on the x-axis, and a capacitive element CAP2 is disposed inside the mass body MS1 and inside the mass body MS2 in the vicinity of each of the connecting portion CU3 and the connecting portion CU4 disposed on the y-axis. Further, in Modification Example 4, as illustrated in FIG. 22, the capacitive elements CAP3 are also disposed in the direction of 30 degrees from the x-axis and the direction of 60 degrees from the x-axis, respectively. That is, in Modification Example 4, the capacitive element (the capacitive element CAP1, CAP2, or CAP3) is disposed every 30 degrees. Thus, according to Modification Example 4, it is possible to control the vibration of the mass body MS1 and the mass body MS2 on different axes.

### MODIFICATION EXAMPLE 5

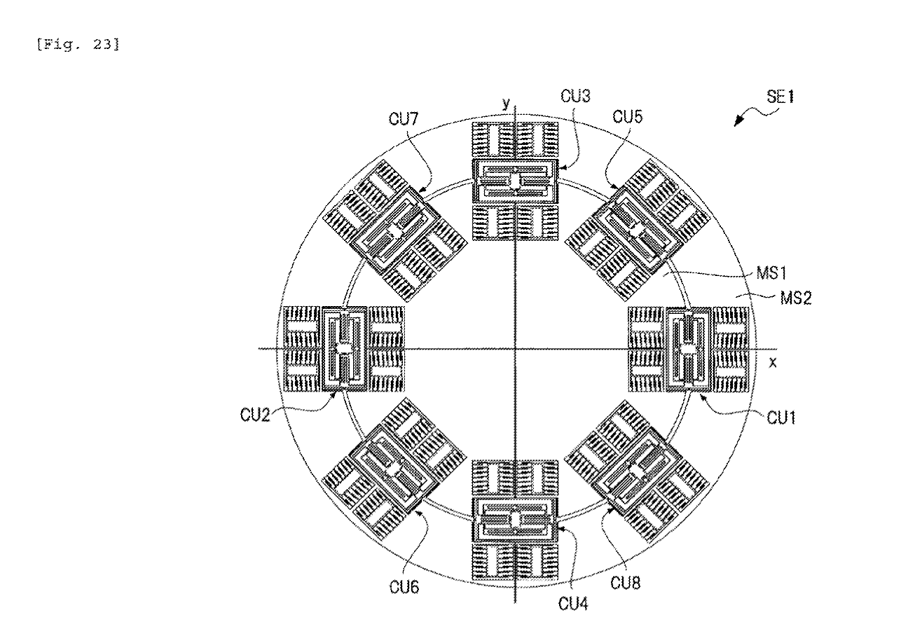

FIG. 23 is a plan view illustrating a configuration of a sensor element SE1 in Modification Example 5. As illustrated in FIG. 23, the sensor element SE1 in Modification Example 5 has for example, eight connecting portions (unit connecting portions) CU1 to CU8. Specifically, the connecting portion CU1 and the connecting portion CU2 are disposed at positions symmetrical with respect to the center of the mass body MS1 in the x-direction, and the connecting portion CU3 and the connecting portion CU4 are disposed at positions symmetrical with respect to the center of the mass body MS1 in the y-direction. The connecting portion CU5 and the connecting portion CU6 are disposed at positions symmetrical with respect to the center of the mass body MS1 in the direction of 45 degrees from the x-direction, and the connecting portion CU7 and the connecting portion CU8 are disposed at positions symmetrical with respect to the center of the mass body MS1 in the direction of 135 degrees from the x-direction. Even with this configuration, it is also possible to realise the technical idea in Embodiment 1. That is, the technical idea in Embodiment 1 can use a plurality of unit connecting portions as a connecting portions connecting the mass body MS1 and the mass body MS1 constituting the sensor element SE1, the number of the plurality of unit connecting portions is not particularly limited, and for example, four connecting portions (unit connecting portions) CU1 to CU4 may be used as in Embodiment 1 or eight connecting portions (unit connecting portions) CU1 to CU8 may be used as in Modification Example 5.

### Embodiment 2

### Basic idea of Embodiment 2

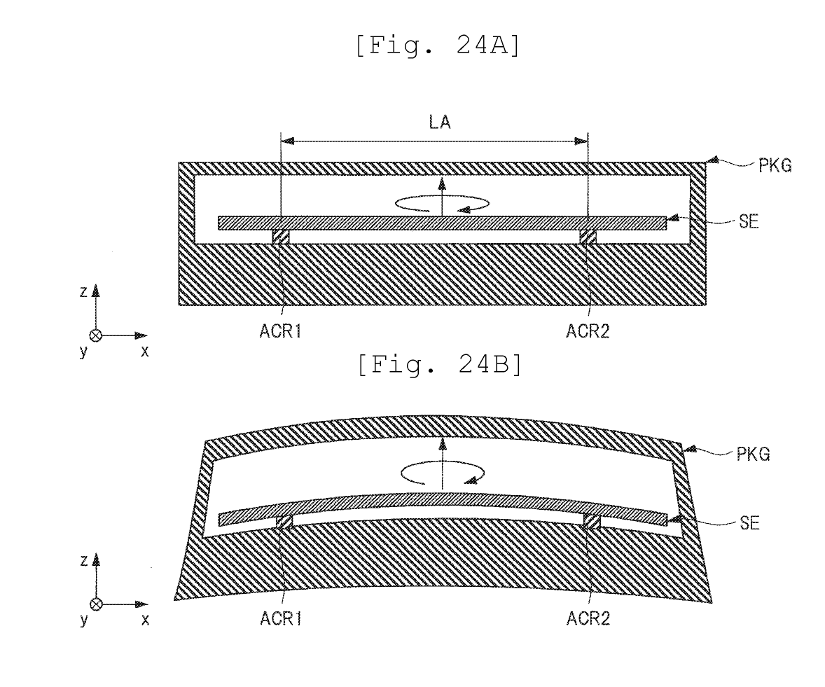

First, the basic idea of Embodiment 2 will be described with reference to the drawings. FIG. 24(a) and FIG. 24(b) are diagrams for explaining a room for improvement focused on Embodiment 2. In FIG. 24(a), the sensor element SE is disposed inside the cavity provided in a package PKG, and the sensor element SE is fixed to the package PKG by the fixing portion ACR1 and fixing portion ACR2. Here, as illustrated in FIG. 24(a), the distance between the fixing portion ACR1 and fixing portion ACR2 is indicated as a distance LA, for example.

Here, with respect to the package PKG, for example, from the viewpoint of cost reduction, plastic packages or the like are used. In this case, for example, as in FIG. 24(b), the package PKG is deformed one to a temperature change and a humidity change due to a change in the external environment. Then, with the deformation of the package PKG, the distance LA between the fixing portion ACR1 and the fixing portion ACR2 changes, which causes a deformation in the sensor element SE. When the sensor element SE is deformed in this manner, stress is applied to the sensor element SE, and as a result, a drift error is added to the detection of an angular velocity and a rotation angle. If the drift error increases, it becomes difficult to detect an angular velocity and a rotation angle. Therefore, in order to improve the performance of the gyroscope, it is necessary that the gyroscope (sensor element SE) is less susceptible to the external environment.

Thus, in Embodiment 2, a study on realizing the structure of a gyroscope (sensor element SE) less susceptible to the external environment. First, the basic idea for the study will be described below, and then a specific configuration example embodying the basic idea will be described.

FIG. 25(a) and FIG. 25(b) are diagrams for explaining the basic idea of Embodiment 2. As illustrated in FIG. 25(a), the sensor element SE is disposed inside the cavity provided in a package PKG, and the sensor element SE is fixed to the package PKG by the fixing portion ACR1 and fixing portion ACR2. Here, as illustrated in FIG. 25(a), the distance between the fixing portion ACR1 and fixing portion ACR2 is indicated as a distance LB, for example. The distance LB is shorter than the distance LA illustrated in FIG. 24(a). In other words, the basic idea in Embodiment 2 is to shorten a distance between the fixing portion ACR1 and the fixing portion ACR2 which fixes the sensor element SE to the package PKG, as can be seen by comparing FIG. 24(a) with FIG. 25(a) (the tenth feature point).

Thus, for example, as illustrated in FIG. 25(b), even if the package PKG is deformed due to changes in the external environment, such as temperature changes and humidity changes, if the distance LB between the fixing portion ACR1 and the fixing portion ACR2 is shortened, the change in the distance LB between the fixing portion ACR1 and the fixing portion ACR2 is reduced, whereby the deformation of the sensor element SE is suppressed. In other words, according to the basic idea in Embodiment 2, even if the package PKG is deformed due to the change of the external environment, the sensor element SE less susceptible to the deformation of the package PKG due to the above-described tenth feature point. That is, according to the basic idea in Embodiment 2, it is possible to realize a gyroscope (sensor element SE) that is robust against a change in the external environment, thereby improving the performance of the gyroscope according to Embodiment 2.

### SPECIFIC CONFIGURATION EXAMPLE

<<Planar Configuration of Sensor Element>>

The specific configuration example of the sensor element SE2 embodying the basic idea of Embodiment 2 will be described below with reference to the drawings.

FIG. 26 is a plan view illustrating an example of a configuration of a sensor element SE2 in Embodiment 2. In FIG. 26, the feature point in Embodiment 2 is that in plan view, the mass body MS1 has a concave portion 20a toward the center of the mass body MS1, the mass body MS2 has a convex portion 30a inserted to the concave portion 20a through the gap SP, and the connecting portion CU1 connects the concave portion 20a and the convex portion 30a. Similarly, the feature point in Embodiment 2 is that in plan view, the mass body MS1 has a concave portion 20b toward the center of the mass body MS1, the mass body MS2 has a convex portion 30b inserted to the concave portion 20b through the gap SP, and the connecting portion CU2 connects the concave portion 20b and the convex portion 30b.

Thus, as illustrated in FIG. 26, the distance between the connecting portion CU1 and the connecting portion CU2 can be shortened. That is, it is possible to shorten the distance between one fixing portion which is a constituent element of the connecting portion CU1 and the other fixing portion which is a constituent element of the connecting portion CU2. Similarly, as illustrated in FIG. 26, the distance between the connecting portion CU3 and the connecting portion CU4 can be shortened. In this way, in the sensor element SE2 illustrated in FIG. 26, by forming the concave portions (20a, 20b) and the convex portions (30a, 30b) toward the center of the sensor element SE1, the connecting portions CU1 to CU4 can be brought close to the center of the sensor element SE1. In this way, in the sensor element SE2 illustrated in FIG. 26, the basic idea of shortening the distance between the fixing portions by forming the concave portions (20a, 20b) and the convex portions (30a, 30b) toward the center of the sensor element SE1 is embodied. Therefore, according to the sensor element SE2 illustrated in FIG. 26, it is possible to realise a gyroscope (sensor element SE2) that is robust against a change in the external environment, thereby improving the performance of the gyroscope according to Embodiment 2.

In the sensor element SE2 illustrated in FIG. 26, as a result of adopting the configuration of bringing the connecting portion CU1 to the connecting portion CU4 close to the center of the mass body MS1, a study on the arrangement of the capacitive elements (the vibration driving unit 10 (13), the monitor portions 11 (14) and 12 (15), and the tuning unit 16 (17)) is also made. That is, as illustrated in FIG. 26, in the sensor element SE2 in Embodiment 2, capacitive elements are disposed outside the connecting portions CU1 to CU4 concentrated in the center of the mass body MS1. In particular, in Embodiment 2, the capacitive elements (the vibration driving unit 10, the monitor portions 11 and 12, and the tuning unit 16) related to the driven vibration in the x-direction are disposed along the imaginary line VL2 extending in the y-direction, and the capacitive elements (the vibration driving unit 13, the monitor portions 14 and 15, and the tuning unit 17) related to the driven vibration in the y-direction are disposed along the imaginary line VL1 extending in the x-direction. Thus, since a capacitive element is not disposed inside the connecting portions CU1 to CU4, a configuration for bringing the connecting portions CU1 to the connecting portion CU4 closer to the center of the mass body MS1 is realized. That is, in Embodiment 2, the basic idea in Embodiment 2 embodied by combining the configuration of forming the concave portions (20a, 20b) and the convex portions (30a, 30b) toward the center of the sensor element SE1 and the configuration in which the capacitive element is not disposed inside the connecting portions CU1 to CU4. As a result, according to Embodiment 2, it is possible to realise a gyroscope (sensor element SE2) which is robust against a change in the external environment.

<<Sectional Configuration of Sensor Element>>

FIG. 27 is a cross-sectional view taken along line A-A of FIG. 26. As illustrated in FIG. 27, in the sensor element SE2 in Embodiment 2, a mass body MS1 is formed on the device layer 1c, and a connecting portion CU1 including a fixing portion ACR1 and a connecting portion CU2 including a fixing port ion ACR2 are formed so as to interpose the mass body MS1. A mass body MS2 is formed outside the connecting portion. CU1 and outside the connecting portion CU1.

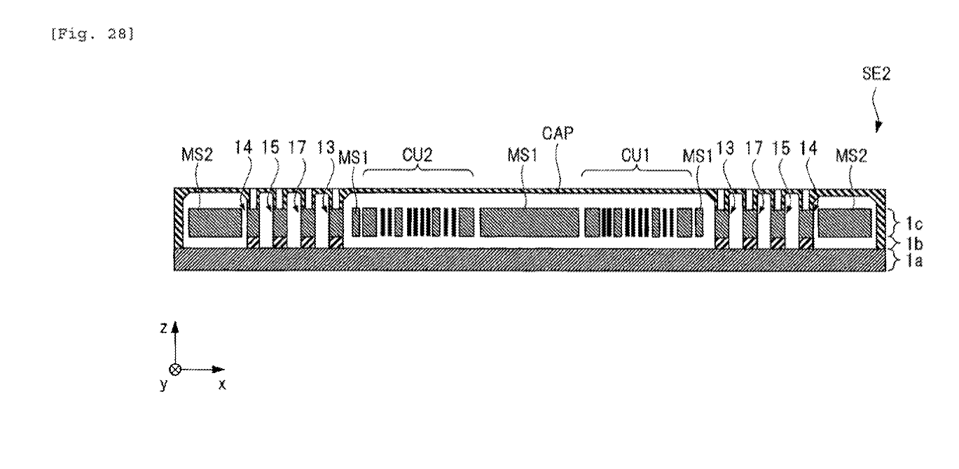

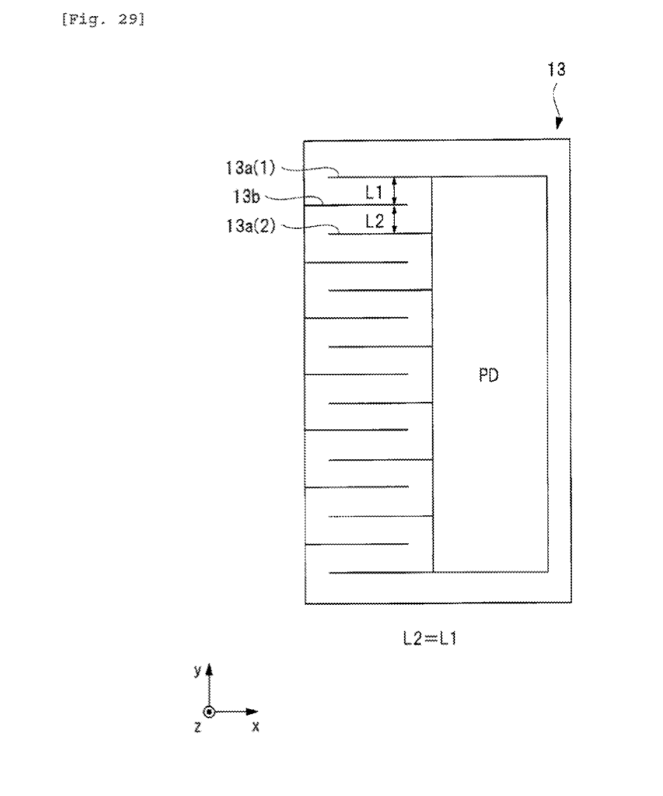

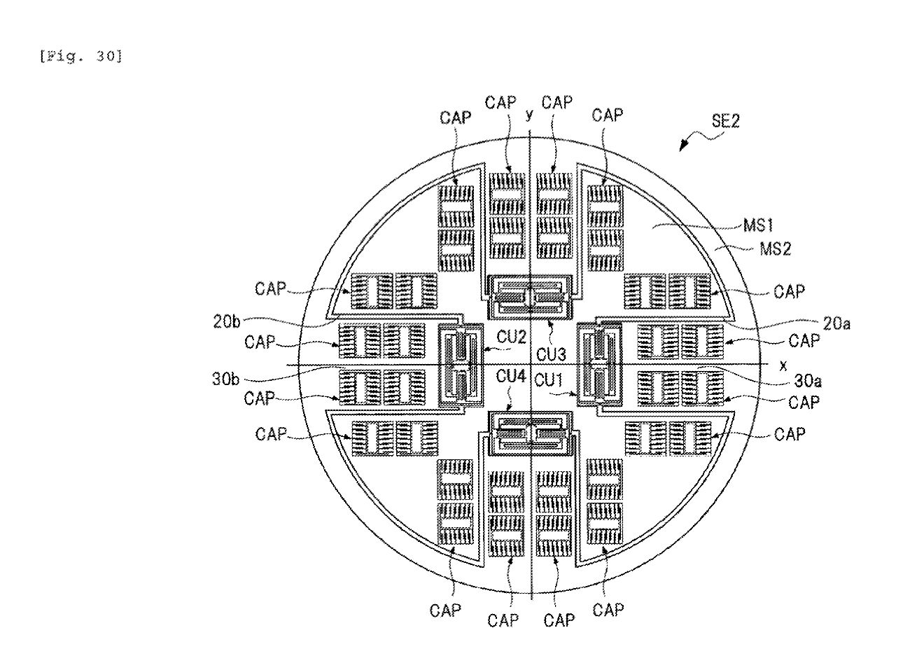

FIG. 28 is a cross-sectional view taken along line B-B of FIG. 26. As illustrated in FIG. 28, in the sensor element SE2 in Embodiment 2, a mass body MS1 is formed on the device layer 1c, and a connecting portion CU1 and a connecting port ion CU2 are formed so as to interpose the mass body MS1. A mass body MS2 is formed outside the connecting portion CU1, and a vibration driving unit 13, a tuning unit 17, a monitor portion 15, and a monitor portion 14 are formed between the connecting portion CU1 and the mass body MS2. Similarly, a mass body MS2 is formed outside the connecting portion CU2, and the vibration driving unit 13, the tuning unit 17, the monitor portion 15 and the monitor portion 14 are formed between the connecting portion CU2 and the mass body MS2.

<<Configuration of Capacitive Element>>

Next, the configuration of the capacitive element included in the sensor element SE2 in Embodiment 2 will be described. FIG. 29 is a schematic diagram illustrating a configuration example of the vibration driving unit 13. As illustrated in FIG. 29, the vibration driving unit 13 is configured with, for example, a capacitive element of a comb structure. Specifically, the vibration driving unit 13 has a fixed electrode 13a(1) and a fixed electrode 13a(2) electrically connected to a pad PD functioning as a connection terminal to the outside, and a movable electrode 13b integrally formed with the mass body MS1 (mass body MS2) so as to be interposed between the fixed electrode 13a(1) and the fixed electrode 13a(2). At this time, for example, it is configured such that a distance L1 between the fixed electrode 13a(1) and the movable electrode 13b is equal to a distance L2 between the fixed electrode 13a(2) and the movable electrode 13b. In this way, in a case of configuring the vibration driving unit 13 with the capacitive elements illustrated in FIG. 29, it is possible to increase the amplitude of the driven vibration of the mass body MS1 (mass body MS2) as compared with the capacitive element illustrated in FIG. 8, thereby improving the detection sensitivity of the rotation angle.

### MODIFICATION EXAMPLE

FIG. 30 is a plan view illustrating a configuration of a sensor element SE2 in Modification Example. As illustrated in FIG. 30, the sensor element SE2 in Modification Example uses a capacitive element of a parallel structure illustrated in FIG. 8 as the capacitive element CAP. That is, the difference is that the capacitive element of the comb structure illustrated in FIG. 29 is used in the sensor element SE2 in Embodiment 2 illustrated in FIG. 26 whereas the capacitive element of the parallel structure illustrated in FIG. 8 is used in the sensor element SE2 in Modification Example illustrated in FIG. 30, and the other configurations are the same. In this way, it can be seen that the basic idea in Embodiment 2 can be embodied even in either the specific configuration example using the capacitive element of the parallel structure illustrated in FIG. 8 or the specific configuration example using the capacitive element of the comb structure illustrated in FIG. 29.

Hitherto, the invention made by the present inventors has been specifically described based on the embodiments, but the present invention is not limited to the embodiments, and various modifications are possible within a scope without departing from the spirit.

### REFERENCE SIGNS LIST

10 VIBRATION DRIVING UNIT

11 MONITOR PORTION

12 MONITOR PORTION

13 VIBRATION DRIVING UNIT

14 MONITOR PORTION

15 MONITOR PORTION

ACR FIXING PORTION

BEAM BM1

BEAM BM2

BEAM BM3

BEAM BM4

BEAM BM5

CU1 CONNECTING PORTION (UNIT CONNECTING PORTION)

CU2 CONNECTING PORTION (UNIT CONNECTING PORTION)

CU3 CONNECTING PORTION (UNIT CONNECTING PORTION)

CU4 CONNECTING PORTION (UNIT CONNECTING PORTION)

MS1 MASS BODY

MS2 MASS BODY

SH1 SHUTTLE

SH2 SHUTTLE

1. A gyroscope comprising:
a first mass body that is displaceable in a first direction and a second direction orthogonal to the first direction;
a second mass body that is displaceable in the first direction and the second direction; and
a connecting portion that is provided between the first mass body and the second mass body, and connects the first mass body with the second mass body,
wherein the connecting portion is configured with a connection structure including
a fixing portion fixed to a substrate,
a first member provided between the fixing portion and the first mass body,
a second member provided between the fixing portion and the second mass body,
a first beam connecting the fixing portion with the first member,
a second beam connecting the fixing portion with the second member,
a third beam connecting the first mass body with the first member,
a fourth beam connecting the second mass body with the second member, and
a fifth beam connecting the first member with the second member, and
wherein the fixing portion is provided between the first member and the second member.

2. The gyroscope according to claim 1,
wherein the first beam is softer in the first direction than in the second direction,
the second beam is softer in the first direction than in the second direction,
the third beam is softer in the second direction than in the first direction, and
the fourth beam is softer in the second direction than in the first direction.

3. The gyroscope according to claim 2,
wherein the first beam is longer in the second direction than in the first direction and has a folded structure in the second direction, and
the second beam is longer in the second direction than in the first direction and has a folded structure in the second direction.

4. The gyroscope according to claim 2,
wherein the third beam is longer in the first direction than in the second direction and has a folded structure in the first direction, and
the fourth beam is longer in the first direction than in the second direction and has a folded structure in the first direction.

5. The gyroscope according to claim 1,
wherein with respect to a first imaginary line passing through the center of the fixing portion and extending in the first direction, the first member has a symmetrical shape, and the second member also has a symmetrical shape.

6. The gyroscope according to claim 1,
wherein the first member and the second member are disposed symmetrically with respect to a second imaginary line passing through the center of the fixing portion and extending in the second direction.

7. The gyroscope according to claim 1,
wherein the mass of the first mass body and the mass of the second mass body are equal to each other.

8. The gyroscope according to claim 7,
wherein the center of the first mass body and the center of the second mass body coincide with each other.

9. The gyroscope according to claim 1,
wherein the connecting portion has a plurality of unit connecting portions, and
each of the plurality of unit connecting portions is configured with the connection structure.

10. The gyroscope according to claim 9,
wherein the plurality of unit connecting portions include
a first unit connecting portion disposed on a first imaginary line passing through the center of the first mass body and extending in the first direction,
a second unit connecting portion disposed on the first imaginary line, at a position symmetrical to the first unit connecting portion with respect to the center of the first mass body,
a third unit connecting portion disposed on a second imaginary line passing through the center of the first mass body and extending in the second direction, and
a fourth unit connecting portion disposed on the second imaginary line, at a position symmetrical to the third unit connecting portion with respect to the center of the first mass body.

11. The gyroscope according to claim 10,
wherein the arrangement direction of the first unit connecting portion and the arrangement direction of the third unit connecting portion differ by 90 degrees, and
the arrangement direction of the second unit connecting portion and the arrangement direction of the fourth unit connecting portion differ by 90 degrees.

12. The gyroscope according to claim 1,
wherein the gyroscope is a rate integrating gyroscope that mechanically detects a rotation angle based on a Coriolis force.

13.-16. (canceled)
